(19) United States
(12) Patent Application Publication
(10) Pub. No.: US 2025/0393408 A1
(43) Pub. Date: Dec. 25, 2025

(54) DISPLAY DEVICE, METHOD OF MANUFACTURING THE DISPLAY DEVICE, AND ELECTRONIC DEVICE

(71) Applicant: Samsung Display Co., LTD., Yongin-si (KR)

(72) Inventors: Jin Su BYUN, Yongin-si (KR); Yeong Woo KWON, Yongin-si (KR); Byung Soo SO, Yongin-si (KR); Pil Soon HONG, Yongin-si (KR)

(21) Appl. No.: 19/220,683

(22) Filed: May 28, 2025

(30) Foreign Application Priority Data
Jun. 20, 2024 (KR) 10-2024-0080523
Jul. 31, 2024 (KR) 10-2024-0102090

(51) Int. Cl. H10K 59/122; H10K 59/12; H10K 59/80

(52) U.S. Cl. CPC H10K 59/122; H10K 59/1201; H10K 59/873

(57) ABSTRACT

A display device includes a first electrode, a pixel defining layer on the first electrode, where a light emitting opening is defined through, a partition wall on the pixel defining layer, where a partition wall opening overlapping the light emitting opening is defined through the partition wall, a light emitting layer in the light emitting opening and the partition wall opening, a second electrode on the light emitting layer, an encapsulation layer on the second electrode and the partition wall, and an organic layer covering the encapsulation layer. An edge portion of the encapsulation layer is spaced apart from the partition wall, and the organic layer is filled in a space between the edge portion of the encapsulation layer and the partition wall.

This application claims priority to Korean patent application No. 10-2024-0080523, filed on Jun. 20, 2024, and Korean patent application No. 10-2024-0102090, filed on Jul. 31, 2024, and all the benefits accruing therefrom under 35 U.S.C. § 119, the contents of which in their entireties are herein incorporated by reference.

### BACKGROUND

### 1. Field

The disclosure generally relates to a display device, a method of manufacturing the display device, and an electronic device.

### 2. Related Art

Recently, as interest in information displays is increased, research and development of display devices have been continuously conducted.

### SUMMARY

Embodiments provide a display device and a method of manufacturing the display device, in which cracks of an encapsulation layer can be prevented and manufacturing processes can be simplified.

In accordance with an embodiment of the disclosure, a display device includes: a first electrode; a pixel defining layer on the first electrode, where a light emitting opening is defined through the pixel defining layer; a partition wall on the pixel defining layer, where a partition wall opening overlapping the light emitting opening is defined through the partition wall; a light emitting layer in the light emitting opening and the partition wall opening; a second electrode on the light emitting layer; an encapsulation layer on the second electrode and the partition wall; and an organic layer covering the encapsulation layer, where an edge portion of the encapsulation layer is spaced apart from the partition wall, and the organic layer is filled in a space between the edge portion of the encapsulation layer and the partition wall.

In an embodiment, any cavity or void may not exist in the space between the edge portion of the encapsulation layer and the partition wall.

In an embodiment, the display device may further include an upper encapsulation layer on the organic layer.

In an embodiment, the upper encapsulation layer may include a first upper encapsulation layer, a second upper encapsulation layer on the first upper encapsulation layer, and a third upper encapsulation layer on the second upper encapsulation layer.

In an embodiment, the light emitting layer may include a first light emitting layer, a second light emitting layer, and a third light emitting layer, which emit lights of different colors. In such an embodiment, the encapsulation layer may include a first encapsulation layer on the first light emitting layer, a second encapsulation layer on the second light emitting layer, and a third encapsulation layer on the third light emitting layer.

In an embodiment, an edge portion of each of the first encapsulation layer, the second encapsulation layer, and the third encapsulation layer may be spaced apart from the partition wall in a thickness direction. In such an embodiment, the organic layer may include a first organic layer covering the partition wall and the first encapsulation layer, a second organic layer covering the first organic layer and the second encapsulation layer, and a third organic layer covering the second organic layer and the third encapsulation layer.

In an embodiment, the first organic layer may be filled in a space between the edge portion of the first encapsulation layer and the partition wall.

In an embodiment, the edge portion of the second encapsulation layer may be spaced apart from the first organic layer, and the edge portion of the third encapsulation layer may be spaced apart from the second organic layer.

In an embodiment, the second organic layer may be filled in a space between the edge portion of the second encapsulation layer and the first organic layer.

In an embodiment, the third organic layer may be filled in a space between the edge portion of the third encapsulation layer and the second organic layer.

In an embodiment, an opening overlapping the second light emitting layer may be defined through the first organic layer. In such an embodiment, the second encapsulation layer may be in the opening of the first organic layer.

In an embodiment, an opening overlapping the third light emitting layer may be defined through the second organic layer. In such an embodiment, the third encapsulation layer may be in the opening of the second organic layer.

In an embodiment, an opening overlapping the opening of the second organic layer may be defined through the first organic layer. In such an embodiment, the third encapsulation layer may be in the opening of the first organic layer.

In accordance with another embodiment of the disclosure, a method of manufacturing a display device includes: providing a base layer on which a first electrode, a pixel defining layer on the first electrode, and a partition wall on the pixel defining layer are formed; forming a first partition wall opening by etching the partition wall; forming a first light emitting opening overlapping the first partition wall opening by etching the pixel defining layer; forming a first light emitting layer in the first light emitting opening and the first partition wall opening; forming a first encapsulation layer on the first light emitting layer and the partition wall; and forming a first organic layer to cover the first encapsulation layer, where the first organic layer is filled in a space formed between an edge portion of the first encapsulation layer and the partition wall.

In an embodiment, the first organic layer may include a low-temperature curable photosensitive resin composition.

In an embodiment, the method may further include: forming a second encapsulation layer on the second light emitting layer and the partition wall; and forming a second organic layer to cover the first organic layer and the second encapsulation layer. In such an embodiment, the second organic layer may be filled in a space formed between an edge portion of the second encapsulation layer and the first organic layer.

In an embodiment, the method may further include: forming a second partition wall opening by etching the partition wall through an opening of the first organic layer; forming a second light emitting opening overlapping the second partition wall opening by etching the pixel defining layer; and forming a second light emitting layer in the second light emitting opening and the second partition wall opening.

In an embodiment, the method may further include: forming a third partition wall opening by etching the partition wall through an opening of the second organic layer; forming a third light emitting opening overlapping the third partition wall opening by etching the pixel defining layer; and forming a third light emitting layer in the third light emitting opening and the third partition wall opening.

In an embodiment, the method may further include: forming a third encapsulation layer on the third light emitting layer and the partition wall; and forming a third organic layer to cover the second organic layer and the third encapsulation layer. In such an embodiment, the third organic layer may be filled in a space formed between an edge portion of the third encapsulation layer and the second organic layer.

In an embodiment, the method may further include forming an upper encapsulation layer on the third organic layer.

In accordance with an embodiment of the disclosure, an electronic device includes: a processor to provide input image data; and a display device to display an image based on the input image data, wherein the display device comprises a first electrode; a pixel defining layer on the first electrode, where a light emitting opening is defined through the pixel defining layer; a partition wall on the pixel defining layer, where a partition wall opening overlapping the light emitting opening is defined through the partition wall; a light emitting layer in the light emitting opening and the partition wall opening; a second electrode on the light emitting layer; an encapsulation layer on the second electrode and the partition wall; and an organic layer covering the encapsulation layer, where an edge portion of the encapsulation layer is spaced apart from the partition wall, and the organic layer is filled in a space between the edge portion of the encapsulation layer and the partition wall.

### BRIEF DESCRIPTION OF THE DRAWINGS

The above and other features of embodiments of the invention will become more apparent by describing in further detail embodiments thereof with reference to the accompanying drawings.

FIG. 1 is a block diagram illustrating an embodiment of a display device.

FIG. 2 is a block diagram illustrating an embodiment of any one of sub-pixels shown in FIG. 1.

FIG. 3 is a circuit diagram illustrating an embodiment of the sub-pixel shown in FIG. 2.

FIG. 4 is a plan view illustrating an embodiment of a display panel shown in FIG. 1.

FIG. 5 is a plan view illustrating an embodiment of a pixel shown in FIG. 4.

FIG. 6 is a sectional view taken along line A-A′ shown in FIG. 5 showing an embodiment.

FIG. 7 is an enlarged view of area B shown in FIG. 6.

FIG. 8 is a sectional view taken along line A-A′ shown in FIG. 5 showing another embodiment.

FIG. 9 is a sectional view taken along line A-A′ shown in FIG. 5 showing another embodiment.

FIG. 10 is a plan view illustrating another embodiment of a pixel shown in FIG. 4.

FIG. 11 is a plan view illustrating another embodiment of a pixel shown in FIG. 4.

FIGS. 12 to 22 are sectional views illustrating processes of a method of manufacturing a display device in accordance with an embodiment of the disclosure.

FIG. 23 is a sectional view illustrating processes of a method of manufacturing a display device in accordance with an embodiment of the disclosure.

FIGS. 24 to 30 are sectional views illustrating processes of a method of manufacturing a display device in accordance with an embodiment of the disclosure.

FIG. 31 is a block diagram of an electronic device according to an embodiment.

FIG. 32 shows schematic views of various embodiments of an electronic device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. It will be understood that when an element is referred to as being “connected” or “coupled” to another element, it can be directly connected or coupled to the another element or be indirectly connected or coupled to the another element with one or more intervening elements interposed therebetween. It will be understood that when an element is referred to as being “between” two elements, it can be the only element between the two elements, or one or more intervening elements may also be present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from X, Y, and Z” can be construed as X only, Y only, Z only, or any combination of two or more items X, Y, and Z (e.g., XYZ, XYY, YZ, ZZ).

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

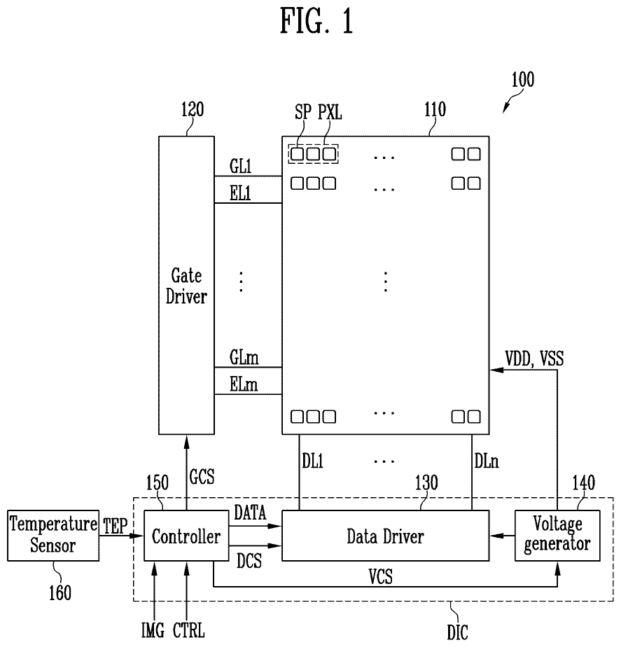

FIG. 1 is a block diagram illustrating an embodiment of a display device.

Referring to FIG. 1, an embodiment of the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn. Here, m and n are integers greater than 1.

Each of the sub-pixels SP may include at least one light emitting element configured to generate light. Accordingly, each of the sub-pixels SP may generate light of a specific color such as red, green, blue, cyan, magenta or yellow. Two or more sub-pixels among the sub-pixels SP may constitute one pixel PXL. In an embodiment, for example, three sub-pixels SP may constitute one pixel PXL as shown in FIG. 1.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating a start of each frame, a horizontal synchronization signal for outputting gate signals in synchronization with timings at which data signals are applied, and the like.

In an embodiment, first to m-th emission control lines EL1 to ELm connected to the sub-pixels SP in the row direction may be further provided. The gate driver 120 may include an emission control driver configured to control the first to m-th emission control lines EL1 to ELm, and the emission control driver may operate under the control of the controller 150.

In an embodiment, the gate driver 120 may be disposed at one side of the display panel 110. However, embodiments are not limited thereto. In another embodiment, for example, the gate driver 120 may be divided into two or more drivers which are physically and/or logically divided, and these drivers may be disposed at one side of the display panel 110 and the other side of the display panel 110, which is opposite to the one side. As such, in accordance with embodiments, the gate driver 120 may be disposed in various forms at the periphery of the display panel 110.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, and the like.

The data driver 130 may apply data signals having grayscale voltages corresponding to the image data DATA to the first to n-th data lines DL1 to DLn by using voltages from the voltage generator 140. When a gate signal is applied to each of the first to m-th gate lines GL1 to GLm, data signals corresponding to the image data DATA may be applied to the data lines DL1 to DLn. Accordingly, corresponding sub-pixels SP may generate light corresponding to the data signals. Accordingly, an image may be displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device 100. In an embodiment, for example, the voltage generator 140 may be configured to generate a plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In another embodiment, the first power voltage VDD or the second power voltage VSS may be provided by an external device of the display device 100.

Besides, the voltage generator 140 may generate various voltages. In an embodiment, for example, the voltage generator 140 may generate an initialization voltage applied to the sub-pixels SP. In an embodiment, for example, a predetermined reference voltage may be applied to the first to n-th data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In an embodiment, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In another embodiment, at least one of the data driver 130, the voltage generator 140, and the controller 150 may be provided as a component distinguished from the driver integrated circuit DIC.

The display device 100 may include at least one temperature sensor 160. The temperature sensor 160 may be configured to sense a temperature at the periphery thereof and generate temperature data TEP indicating the sensed temperature. In an embodiment, the temperature sensor 160 may be disposed to be adjacent to the display panel 110 and/or the driver integrated circuit DIC.

The controller 150 may control various operations of the display device 100 in response to the temperature data TEP. In an embodiment, the controller 150 may adjust the luminance of an image output from the display panel 110 in response to the temperature data TEP. In an embodiment, for example, the controller 150 may control components such as the data driver 130 and/or the voltage generator 140, thereby adjusting data signals and the first and second power voltages VDD and VSS.

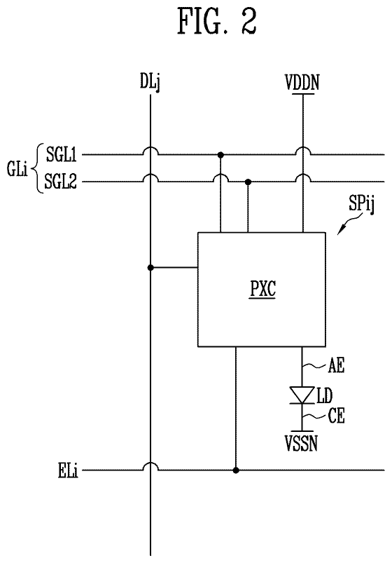

FIG. 2 is a block diagram illustrating an embodiment of any one of the sub-pixels shown in FIG. 1. In FIG. 2, a sub-pixel SPij arranged on an i-th row (i is an integer greater than or equal to 1 and smaller than or equal to m) and a j-th column (j is an integer greater than or equal to 1 and smaller than or equal to n) among the sub-pixels SP shown in FIG. 1 is illustrated as an example.

Referring to FIG. 2, an embodiment of the sub-pixel SPij may include a sub-pixel circuit PXC and a light emitting element LD.

The light emitting element LD may be connected between a first power voltage node VDDN and a second power voltage node VSSN. The first power voltage node VDDN may be a node for transferring the first power voltage VDD shown in FIG. 1, and the second power voltage node VSSN may be a node for transferring the second power voltage VSS shown in FIG. 1.

An anode electrode AE of the light emitting element LD may be connected to the first power voltage node VDDN through the sub-pixel circuit PXC, and a cathode electrode CE of the light emitting element LD may be connected to the second power voltage node VSSN. In an embodiment, for example, the anode electrode AE of the light emitting element LD may be connected to the first power voltage node VDDN through one or more transistors included in the sub-pixel circuit PXC.

The sub-pixel circuit PXC may be connected to an i-th gate line GLi among the first to m-th gate lines GL1 to GLm shown in FIG. 1, an i-th emission control line ELi among the first to m-th emission control lines EL1 to ELm shown in FIG. 1, and a j-th data line DLj among the first to n-th data lines DL1 to DLn shown in FIG. 1. The sub-pixel circuit PXC may be configured to control the light emitting element LD based on signals received through these signal lines.

The sub-pixel circuit PXC may operate in response to a gate signal received through the i-th gate line GLi. The i-th gate line GLi may include one or more sub-gate lines. In an embodiment, as shown in FIG. 2, the i-th gate line GLi may include first and second sub-gate lines SGL1 and SGL2. The sub-pixel circuit PXC may operate in response to gate signals received through the first and second sub-gate lines SGL1 and SGL2. As such, when the i-th gate line GLi includes two or more sub-gate lines, the sub-pixel circuit PXC may operate in response to gate signals received through the corresponding sub-gate lines.

The sub-pixel circuit PXC may operate in response to an emission control signal received through the i-th emission control line ELi. In an embodiment, the i-th emission control line ELi may include one or more sub-emission control lines. In an embodiment where the i-th emission control line ELi includes two or more sub-emission control lines, the sub-pixel circuit PXC may operate in response to emission control signals receives through the corresponding emission control lines.

The sub-pixel circuit PXC may receive a data signal through the j-th data line DLj. The sub-pixel circuit PXC may store a voltage corresponding to the data signal in response to at least one of the gate signals received through the first and second sub-gate lines SGL1 and SGL2. The sub-pixel circuit PXC may control a current flowing from the first power voltage node VDDN to the second power voltage node VSSN through the light emitting element LD according to the stored voltage in response to the emission control signal received through the i-th emission control line ELi. Accordingly, the light emitting element LD may generate light with a luminance corresponding to the data signal.

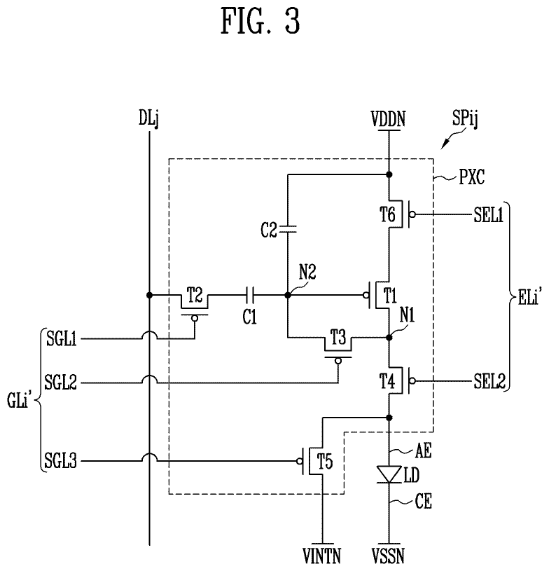

FIG. 3 is a circuit diagram illustrating an embodiment of the sub-pixel shown in FIG. 2.

Referring to FIG. 3, an embodiment of a sub-pixel SPij may include a sub-pixel circuit PXC and a light emitting element LD.

The sub-pixel circuit PXC may be connected to an i-th gate line GLi′, an i-th emission control line ELi′, and a j-th data line DLj. When comparing the i-th gate line GLi′ with the i-th gate line GLi shown in FIG. 2, the i-th gate line GLi′ may further include a third sub-gate line SGL3. In an embodiment, as shown in FIG. 3, the i-th emission control line ELi′ may include a first sub-emission control line SEL1 and a second sub-emission control line SEL2.

The sub-pixel circuit PXC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on based on a voltage level of the second node N2. The first transistor T1 may be designated as a driving transistor.

The second transistor T2 may be connected between the j-th data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2.

The fourth transistor T4 may be connected between the first node N1 and an anode electrode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In an embodiment, the initialization voltage may be provided by the voltage generator 140 shown in FIG. 1. In another embodiment, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

In an embodiment, as described above, the sub-pixel circuit PXC may include the first to sixth transistors T1 to T6 and the first and second capacitors C1 and C2. However, embodiments are not limited thereto. The sub-pixel circuit PXC may be implemented as any one of various types of circuits each including transistors and one or more capacitors. In another embodiment, for example, the sub-pixel circuit PXC may include two transistors and one capacitor. In accordance with embodiments of the sub-pixel circuit PXC, the number of sub-gate lines included in the i-th gate line GLi′ and the number of sub-emission control lines included in the i-th emission control line ELi′ may vary.

In an embodiment, the first to sixth transistors T1 to T6 may be P-type transistors. In an embodiment, each of the first to sixth transistors T1 to T6 may be a metal oxide silicon field effect transistor (MOSEFT). However, embodiments are not limited thereto. In another embodiment, for example, at least one of the first to sixth transistors T1 to T6 may be replaced with an N-type transistor.

In an embodiment, the first to sixth transistors T1 to T6 may include an amorphous silicon semiconductor, a monocrystalline silicon semiconductor, a polycrystalline silicon semiconductor, an oxide semiconductor, or the like.

The light emitting element LD may include the anode electrode AE, a cathode electrode CE, and a light emitting layer. The light emitting layer may be disposed between the anode electrode AE and the cathode electrode CE. After a data signal transferred through the j-th data line DLj is reflected on a voltage of the second node N2, the fourth and sixth transistors T4 and T6 may be turned on when the emission control signals of the first and second sub-emission control lines SEL1 and SEL2 are enabled to a low level. In addition, the first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

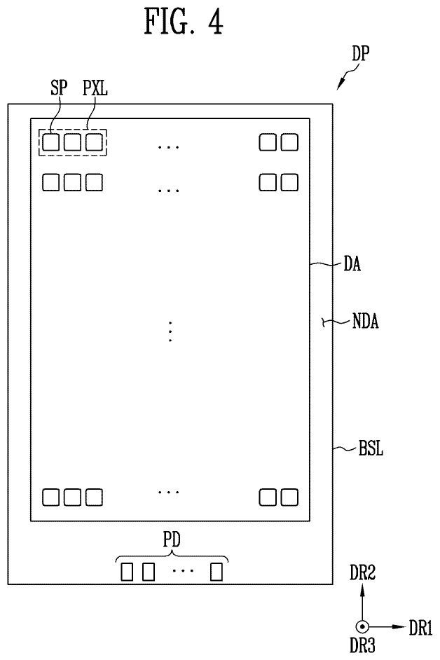

FIG. 4 is a plan view illustrating an embodiment of the display panel shown in FIG. 1.

Referring to FIG. 4, an embodiment of the display panel DP shown in FIG. 1 may include a display area DA and a non-display area NDA. The display panel DP may display an image through the display area DA. The non-display area NDA may be disposed at the periphery of the display area DA.

The display panel DP may include a base layer BSL, sub-pixels SP, and pads PD.

In an embodiment where the display panel DP is used as a display screen of a head mounted display (HMD), a virtual reality (VR) device, a mixed reality (MR) device, an augmented reality (AR) device, or the like, the display panel DP may be located very close to eyes of a user. The sub-pixels SP having a relatively high degree of integration may be required. In order to increase the degree of integration of the sub-pixels SP, the base layer BSL may be provided as a silicon substrate. The sub-pixels SP and/or the display panel DP may be formed on the base layer BSL as the silicon substrate, but the disclosure is not necessarily limited thereto.

The sub-pixels SP may be disposed in the display area DA on the base layer BSL. In an embodiment, the sub-pixels SP may be arranged in a matrix form along a first direction DR1 and a second direction DR2 intersecting the first direction DR1. Here, a third direction DR3 may be a direction perpendicular to the first and second directions DR1 and DR2 or a thickness direction of the display panel DP or the base layer BSL. However, embodiments are not limited thereto. In another embodiment, for example, the sub-pixels SP may be arranged in a zigzag form along the first direction DR1 and the second direction DR2. In another embodiment, for example, the sub-pixels SP may be disposed in a PENTILE™ form. The first direction DR1 may be a row direction, and the second direction DR2 may be a column direction. Two or more sub-pixels among the sub-pixels SP may constitute (or collectively define) one pixel PXL.

A component for controlling the sub-pixels SP may be disposed in the non-display area NDA on the base layer BSL. In an embodiment, for example, lines connected to the sub-pixels SP, such as the first to m-th gate lines GL1 to GLm and the first to n-th data lines DL1 to DLn, which are shown in FIG. 1, may be disposed in the non-display area NDA.

At least one selected from the gate driver 120, the data driver 130, the voltage generator 140, the controller 150, and the temperature sensor 160, which are shown in FIG. 1, may be integrated in the non-display area NDA of the display panel DP. In an embodiment, the gate driver 120 shown in FIG. 1 is mounted on the display panel DP, and may be disposed in the non-display area NDA. In another embodiment, the gate driver 120 may be implemented as an integrated circuit distinguished from the display panel DP. In an embodiment, the temperature sensor 160 may be disposed in the non-display area NDA to sense a temperature of the display panel DP.

The pads PD may be disposed in the non-display area NDA on the base layer BSL. The pads PD may be electrically connected to the sub-pixels SP through the lines. In an embodiment, for example, the pads PD may be connected to the sub-pixels SP through the first to n-th data lines DL1 to DLn.

The pads PD may interface the display panel DP with other components of the display device 100 (see FIG. 1). In an embodiment, voltages and signals, which are necessary for operations of components included in the display panel DP, may be provided from the driver integrated circuit DIC shown in FIG. 1 through the pads PD. In an embodiment, for example, the first to n-th data lines DL1 to DLn may be connected to the driver integrated circuit DIC through the pads PD. In an embodiment, for example, the first and second power voltages VDD and VSS may be received from the driver integrated circuit DIC through the pads PD. In an embodiment where the gate driver 120 is mounted in the display panel DP, the gate control signal GCS may be transmitted from the driver integrated circuit DIC to the gate driver 120 through the pads PD.

In an embodiment, the display area DA may have various shapes. The display area DA may have a closed-loop shape including linear sides and/or curved sides. In an embodiment, for example, the display area DA may have shapes such as a polygon, a circle, a semicircle, and an ellipse.

In an embodiment, the display panel DP may have a flat display surface. In another embodiment, the display panel DP may at least partially have a round display surface. In an embodiment, the display panel DP may be bendable, foldable or rollable. The display panel DP and/or the base layer BSL may include materials having flexibility.

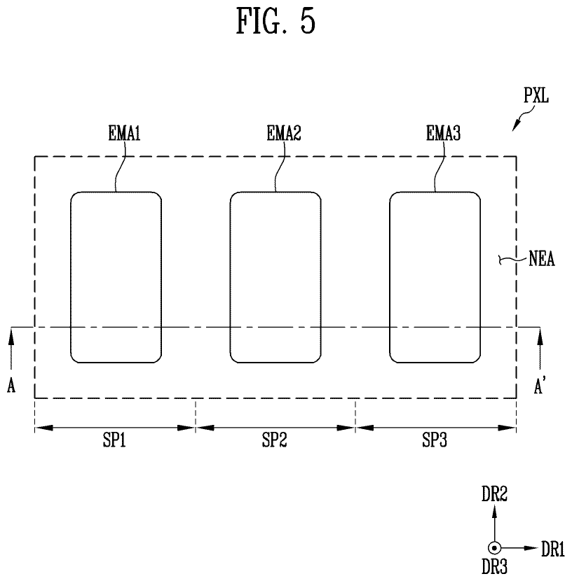

FIG. 5 is a plan view illustrating an embodiment of a pixel shown in FIG. 4.

Referring to FIG. 5, in an embodiment, each of the pixels PXL and PXL2 may include first to third sub-pixels SP1 to SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a light emitting layer corresponding to the first sub-pixel SP1. The second emission area EMA2 may be an area in which light is emitted from a light emitting layer corresponding to the second sub-pixel SP2. The third emission area EMA3 may be an area in which light is emitted from a light emitting layer corresponding to the third sub-pixel SP3.

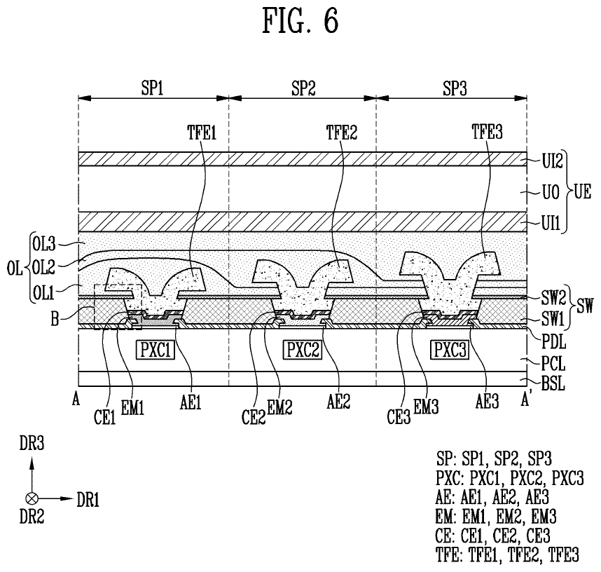

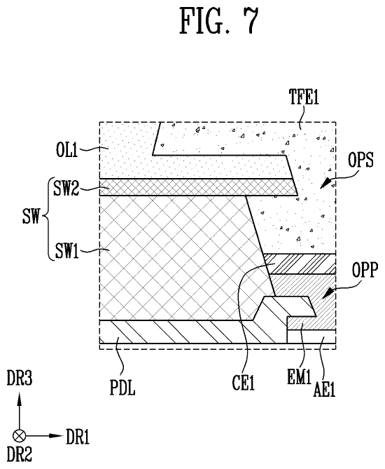

FIG. 6 is a sectional view an embodiment taken along line A-A′ shown in FIG. 5. FIG. 7 is an enlarged view of area B shown in FIG. 6.

Referring to FIGS. 6 and 7, in an embodiment, a base layer BSL may include a glass substrate. In some embodiments, the base layer BSL may include a polyimide (PI) substrate. In some embodiments, the base layer BSL may include a silicon wafer substrate formed using a semiconductor process. The base layer BSL may include a semiconductor material suitable for forming circuit elements, but the disclosure is not necessarily limited thereto.

A pixel circuit layer PCL may be disposed on the base layer BSL. The base layer BSL and/or the pixel circuit layer PCL may include insulating layers and conductive patterns disposed between the insulating layers. The conductive patterns of the pixel circuit layer PCL may define or form a sub-pixel circuit PXC. The sub-pixel circuit PXC may be included in a corresponding sub-pixel SP. In an embodiment, for example, the sub-pixel circuit PXC may include a first sub-pixel circuit PXC1 of the first sub-pixel SP1, a second sub-pixel circuit PXC2 of the second sub-pixel SP2, and a third sub-pixel circuit PXC3 of the third sub-pixel SP3.

Each of the first to third sub-pixel circuits PXC1 to PXC3 may include transistors and one or more capacitors. Each transistor may include a semiconductor portion including a source region, a drain region, and a channel region, and a gate electrode overlapping the semiconductor portion. In an embodiment, where the base layer BSL is provided as a glass substrate or a PI substrate, the semiconductor portion and the gate electrode may be included in the pixel circuit layer PCL. Each capacitor may include electrodes spaced apart from each other. In an embodiment, for example, each capacitor may include electrodes spaced apart from each other on a section. In an embodiment, for example, each capacitor may include electrodes spaced apart from each other in the third direction DR3 with an insulating layer interposed therebetween. In some embodiments, where the base layer BSL is provided as a silicon substrate, the semiconductor portion may be included in the base layer BSL, and the gate electrode may be included as a conductive pattern of the pixel circuit layer PCL in the pixel circuit layer PCL. However, the disclosure is not necessarily limited thereto.

Anode electrodes AE (or first electrodes) may be disposed on the pixel circuit layer PCL. The anode electrode AE may be in contact with the sub-pixel circuit PXC of the pixel circuit layer PCL. The anode electrodes AE may include an opaque conductive material capable of reflecting light, but the disclosure is not necessarily limited thereto.

A first anode electrode AE1 may be disposed in the first sub-pixel SP1. The first anode electrode AE1 may be electrically connected to the first sub-pixel circuit PXC1. A second anode electrode AE2 may be disposed on the second sub-pixel SP2. The second anode electrode AE2 may be electrically connected to the second sub-pixel circuit PXC2. A third anode electrode AE3 may be disposed in the third sub-pixel SP3. The third anode electrode AE3 may be electrically connected to the third sub-pixel circuit PXC3.

A pixel defining layer PDL may be disposed on the anode electrodes AE. The pixel defining layer PDL may define or be provided with a light emitting opening OPP exposing a portion of each of the anode electrodes AE. Emission areas corresponding to the first to third sub-pixels SP1 to SP3 may be defined by the light emitting openings OPP of the pixel defining layer PDL, respectively. Alternatively, it may be understood that emission areas corresponding to the first to third sub-pixels SP1 to SP3 may be defined by the anode electrodes AE, respectively.

In an embodiment, the pixel defining layer PDL may include an inorganic material. In an embodiment, for example, the pixel defining layer PDL may include silicon oxide (SiOₓ) and silicon nitride (SiNₓ). In another embodiment, the pixel defining layer PDL may include an organic material. However, the material of the pixel defining layer PDL is not limited thereto.

A partition wall SW may be disposed on the pixel defining layer PDL. The partition wall SW may be disposed in boundaries of the first to third sub-pixels SP1 to SP3 or between the first to third sub-pixels SP1 to SP3. The partition wall SW may define or be provided with a partition wall opening OPS overlapping with the light emitting opening OPP of the pixel defining layer PDL in the third direction DR3. The partition wall opening OPS of the partition wall SW along with the light emitting opening OPP of the pixel defining layer PDL may expose the anode electrode AE.

The partition wall SW may include a first partition wall SW1 and a second partition wall SW2. The first partition wall SW1 may be disposed on the pixel defining layer PDL. The first partition wall SW1 may be disposed directly on the pixel defining layer PDL. The second partition wall SW2 may be disposed on the first partition wall SW1. The second partition wall SW2 may be disposed directly on the first partition wall SW1.

The partition wall SW may have an undercut shape on a section. In an embodiment, for example, a width of the second partition wall SW2 may be greater than a width of the first partition wall SW1. In an embodiment, for example, the second partition wall SW2 may protrude further than the first partition wall SW1 towards a center of a corresponding partition wall openings OPS in a planar direction, that is, a direction on a plane defined by the first and second directions DR1 and DR2. In an embodiment, for example, the second partition wall SW2 may form a tip protruding from the first partition wall SW1. A thickness of the second partition wall SW2 in the third direction DR3 may be greater than a thickness of the first partition wall SW1 in the third direction DR3, but the disclosure is not necessarily limited thereto. In an embodiment, the second partition wall SW2 may have a characteristic strong against an etching environment as compared with the first partition wall SW1. In an embodiment, for example, the first partition wall SW1 may include aluminum (Al), and the second partition wall SW2 may include titanium (Ti). However, the disclosure is not necessarily limited thereto. The tip of the second partition wall SW2 may function to separate a light emitting layer and/or a cathode electrode CE, which will be described later, from each other.

In an embodiment, the first partition wall SW1 and/or the second partition wall SW2 may include a conductive material. In some embodiments, the first partition wall SW1 and the second partition wall SW2 may include different conductive materials. The first partition wall SW1 and the second partition wall SW2 may be electrically connected to the cathode electrode CE which will be described later to transfer the second power voltage VSS to the cathode electrode CE.

The light emitting layer EM may be disposed on the anode electrodes AE. The light emitting layer EM may be disposed in the light emitting openings OPP of the pixel defining layer PDL and the partition wall openings OPS of the partition wall SW. The light emitting layer EM may be disposed on the anode electrodes AE exposed by the light emitting openings OPP and the partition wall openings OPS.

The light emitting layer EM may include an intermediate layer that generates light, an electron transport layer that transports electrons, a hole transport layer that transports holes, or the like.

The light emitting layer EM may include a first light emitting layer EM1 of the first sub-pixel SP1, a second light emitting layer EM2 of the second sub-pixel SP2, and/or a third light emitting layer EM3 of the third sub-pixel SP3. The first to third light emitting layers EM1 to EM3 may emit lights of different colors. In an embodiment, for example, the first light emitting layer EM1 may emit light of a red color, the second light emitting layer EM2 may emit light of a green color, and the third light emitting layer EM3 may emit light of a blue color. However, the disclosure is not necessarily limited thereto.

The first light emitting layer EM1 may be disposed in the light emitting opening OPP of the pixel defining layer PDL and the partition wall opening OPS of the partition wall SW in the first sub-pixel SP1. The second light emitting layer EM2 may be disposed in the light emitting opening OPP of the pixel defining layer PDL and the partition wall opening OPS of the partition wall SW in the second sub-pixel SP2. The third light emitting layer EM3 may be disposed in the light emitting opening OPP of the pixel defining layer PDL and the partition wall opening OPS of the partition wall SW in the third sub-pixel SP3.

The cathode electrode CE (or second electrode) may be disposed on the light emitting layer EM. The cathode electrode CE may be disposed in the partition wall opening OPS of the partition wall SW. The cathode electrode CE may be a thin metal layer having a thickness to a degree to which light emitted from the light emitting layer EM can be transmitted therethough. The cathode electrode CE may include or be formed of a metal material to have a relatively thin thickness, or include or be formed of a transparent conductive material. In an embodiment, the cathode electrode CE may include at least one selected from various transparent conductive materials including indium tin oxide, indium zinc oxide, indium tin zinc oxide, aluminum zinc oxide, gallium zinc oxide, zinc tin oxide, and gallium tin oxide. In another embodiment, the cathode electrode CE may include at least one selected from silver (Ag), magnesium (Mg), and mixtures thereof. However, the material of the cathode electrode CE is not limited thereto.

The cathode electrode CE may include a first cathode electrode CE1 of the first sub-pixel SP1, a second cathode electrode CE2 of the second sub-pixel SP2, and/or a third cathode electrode CE3 of the third sub-pixel SP3. The first cathode electrode CE1 may be disposed on the first light emitting layer EM1. The second cathode electrode CE2 may be disposed on the second light emitting layer EM2. The third cathode electrode CE3 may be disposed on the third light emitting layer EM3. The first cathode electrode CE1 may be disposed in the partition wall opening OPS of the partition wall SW in the first sub-pixel SP1. The second cathode electrode CE2 may be disposed in the partition wall opening OPS of the partition wall SW in the second sub-pixel SP2. The third cathode electrode CE3 may be disposed in the partition wall opening OPS of the partition wall SW in the third sub-pixel SP3.

Holes injected from the anode electrode AE and electrons injected from the cathode electrode CE may be transported into the intermediate layer to form excitons, and light may be generated when the excitons are changed from an excited state to a ground state. A luminance of the light may be determined based on an amount of current flowing through the intermediate layer. A wavelength band of the generated light may be determined based on a configuration of the intermediate layer.

The first anode electrode AE1, the first light emitting layer EM1 and the first cathode electrode CE1 may constitute (or collectively define) a first light emitting element. The second anode electrode AE2, the second light emitting layer EM2, and the second cathode electrode CE2 may constitute a second light emitting element. The third anode electrode AE3, the third light emitting layer EM3, and the third cathode electrode CE3 may constitute a third light emitting element.

An encapsulation layer TFE may be disposed on the cathode electrode CE and the partition wall SW. The encapsulation layer TFE may cover layers thereunder, including the first to third light emitting elements. The encapsulation layer TFE may prevent oxygen and/or moisture from infiltrating into the first to third light emitting elements. In an embodiment, the encapsulation layer TFE may include an inorganic layer or an organic layer. In an embodiment, for example, the inorganic layer may include silicon nitride (SiNₓ), silicon oxide (SiOₓ), silicon oxynitride (SiOₓNy), or the like. In an embodiment, for example, the organic layer may include an organic material such as acrylic resin, epoxy resin, a phenolic resin, polyamide resin, polyimide resin, unsaturated polyester resin, polyphenylenether resin, polyphenylenesulfide resin, or benzocyclobutene (BCB). However, the materials of the organic layer and the inorganic layer of the encapsulation layer TFE are not limited thereto.

The encapsulation layer TFE may include a first encapsulation layer TFE1 of the first sub-pixel SP1, a second encapsulation layer TFE2 of the second sub-pixel SP2, and/or a third encapsulation layer TFE3 of the third sub-pixel SP3. The first encapsulation layer TFE1 may be disposed on the first cathode electrode CE1. The second encapsulation layer TFE2 may be disposed on the second cathode electrode CE2. The third encapsulation layer TFE3 may be disposed on the third cathode electrode CE3.

The first encapsulation layer TFE1 may be disposed in the partition wall opening OPS of the partition wall SW in the first sub-pixel SP1. The second encapsulation layer TFE2 may be disposed in the partition wall opening OPS of the partition wall SW in the second sub-pixel SP2. The third encapsulation layer TFE3 may be disposed in the partition wall opening OPS of the partition wall SW in the third sub-pixel SP3.

In an embodiment, the first to third encapsulation layers TFE1 to TFE3 may be partially disposed on the partition wall SW (or the second partition wall SW2). An edge portion of each of the first to third encapsulation layers TFE1 to TFE3 may be spaced apart from the partition wall SW (or the second partition wall SW2). In an embodiment, the edge portion of each of the first to third encapsulation layers TFE1 to TFE3 may be spaced apart from an upper surface of the partition wall SW (or the second partition wall SW2) in the third direction DR3 (in the thickness direction of the base layer BSL). Here, the edge portion may mean a portion including an edge or an end in a plan view or when viewed in the third direction DR3. In an embodiment, for example, the edge portion of each of the first to third encapsulation layers TFE1 to TFE3 may be spaced apart from a top surface of the partition wall SW (or the second partition wall SW2) in the third direction DR3. In such an embodiment where an edge portion of the encapsulation layer TFE is spaced apart from a lower layer, stress is concentrated on an area in which the edge portion of the encapsulation layer TFE and the lower layer are spaced apart from each other when external stress is applied or when a panel strain occurs, such as bending of the display panel DP, and therefore, cracks may occur in the encapsulation layer TFE. Accordingly, an encapsulation function may be lost. Thus, in the display device in accordance with the embodiment of the disclosure, the area in which the edge portion of the encapsulation layer TFE and the lower layer are spaced apart from each other in the third direction DR3 is filled with an organic layer OL, such that occurrence of cracks in the encapsulation layer TFE can be effectively prevented.

The organic layer OL may be disposed over (or to cover) the encapsulation layer TFE. The organic layer OL may be disposed (or filled in a space) between the edge portion of the encapsulation layer TFE and the partition wall SW (or the second partition wall SW2). In an embodiment, the organic layer OL may be completely filled between the edge portion of the encapsulation layer TFE and the partition wall SW (or the second partition wall SW2). Accordingly, any space, pore, cavity or void may not exist between the edge portion of the encapsulation layer TFE and the partition wall SW (or the second partition wall SW2), but the disclosure is not necessarily limited thereto. In such an embodiment, where the organic layer OL is filled between the edge portion of the encapsulation layer TFE and the partition wall SW, occurrence of cracks in the encapsulation layer TFE can be effectively prevented even when the edge portion of the encapsulation layer TFE and the partition wall SW are spaced apart from each other in the third direction DR3.

The organic layer OL may include a first organic layer OL1, a second organic layer OL2, and a third organic layer OL3. The first organic layer OL1 may be disposed over the partition wall SW (or the second partition wall SW2) and the first encapsulation layer TFE1. The first organic layer OL1 may be disposed directly over the partition wall SW (or the second partition wall SW2) and the first encapsulation layer TFE1. The first organic layer OL1 may completely cover the first encapsulation layer TFE1. The first organic layer OL1 may be filled between the edge portion of the first encapsulation layer TFE1 and the partition wall SW (or the second partition wall SW2). Accordingly, occurrence of cracks in the first encapsulation layer TFE1 can be prevented.

The first organic layer OL1 may include may define or be provided with an opening overlapping the second sub-pixel SP2 (or the second light emitting layer EM2). The second encapsulation layer TFE2 may be disposed in the opening of the first organic layer OL1.

The first organic layer OL1 may include or be formed of a photosensitive resin composition. The first organic layer OL1 may include or be formed of a transparent photosensitive resin composition such that light emitted from the light emitting layer EM can be transmitted therethrough. The first organic layer OL1 may include or be formed of a low-temperature curable photosensitive resin composition to effectively prevent damage of the light emitting layer EM in a process of forming the first organic layer OL1. In an embodiment, for example, the first organic layer OL1 may include or be formed of a photosensitive resin composition curable at a low temperature in a range of about 70° C. to about 100° C., but the disclosure is not necessarily limited thereto.

The first organic layer OL1 may be formed with different thicknesses in the first to third sub-pixels SP1 to SP3. That is, portions of the first organic layer OL1 in the first to third sub-pixels SP1 to SP3 may have different thicknesses from each other. Here, a thickness of an element in a sub-pixel may mean an average thickness of the element in an area corresponding to the sub-pixel. In an embodiment, for example, a thickness of the first organic layer OL1 of the first sub-pixel SP1 in the third direction DR3 may be greater than a thickness of the first organic layer OL1 of the second sub-pixel SP2 in the third direction DR3 and/or a thickness of the first organic layer OL1 of the third sub-pixel SP3 in the third direction DR3. In an embodiment, the thickness of the first organic layer OL1 of the second sub-pixel SP2 in the third direction DR3 and/or the thickness of the first organic layer OL1 of the third sub-pixel SP3 in the third direction DR3 may be about 2.2 micrometers (μm) or greater. In a case where the thickness of the first organic layer OL1 of the second sub-pixel SP2 in the third direction DR3 and/or the thickness of the first organic layer OL1 of the third sub-pixel SP3 in the third direction DR3 is formed to be less than about 2.2 μm, the first organic layer OL1 may not be sufficiently filled between the edge portion of the first encapsulation layer TFE1 and the partition wall SW. Accordingly, a pore, cavity or void exists between the edge portion of the first encapsulation layer TFE1 and the partition wall SW, and therefore, cracks may occur in the first encapsulation layer TFE1.

The second organic layer OL2 may be disposed over the first organic layer OL1 and the second encapsulation layer TFE2. The second organic layer OL2 may be disposed directly over the first organic layer OL1 and the second encapsulation layer TFE2. The second organic layer OL2 may completely cover the first organic layer OL1 and/or the second encapsulation layer TFE2.

In an embodiment, the first organic layer OL1 may be disposed on the partition wall SW (or the second partition wall SW2), and the edge portion of the second encapsulation layer TFE2 may be spaced apart from a top surface of the first organic layer OL1 in the third direction DR3. The second organic layer OL2 may be filled between the edge portion of the second encapsulation layer TFE2 and the first organic layer OL1. That is, the first organic layer OL1 and the second organic layer OL2 may be filled between the edge portion of the second encapsulation layer TFE2 and the partition wall SW (or the second partition wall SW2). Accordingly, occurrence of cracks in the second encapsulation layer TFE2 can be effectively prevented.

The second organic layer OL2 may define or be provided with an opening overlapping the third sub-pixel SP3 (or the third light emitting layer EM3). The third encapsulation layer TFE3 may be disposed in the opening of the second organic layer OL2. The first opening OL1 may further include or be provided with an opening overlapping the opening of the second organic layer OL2. The third encapsulation layer TFE3 may be disposed in the opening of the first organic layer OL1.

The second organic layer OL2 may include or be formed of a photosensitive resin composition. The second organic layer OL2 may include or be formed of a transparent photosensitive resin composition such that light emitted from the light emitting layer EM can be transmitted therethrough. The second organic layer OL2 may include or be formed of a low-temperature curable photosensitive resin composition to effectively prevent damage of the light emitting layer EM in a process of forming the second organic layer OL2. In an embodiment, for example, the second organic layer OL2 may include or be formed of a photosensitive resin composition curable at a low temperature in a range of about 70° C. to about 100° C., but the disclosure is not necessarily limited thereto. The second organic layer OL2 may include a same material as the first organic layer OL1, but the disclosure is not necessarily limited thereto.

The second organic layer OL2 may be formed with different thicknesses in the first to third sub-pixels SP1 to SP3. That is, portions of the second organic layer OL2 in the first to third sub-pixels SP1 to SP3 may have different thicknesses from each other. In an embodiment, for example, a thickness of the second organic layer OL2 of the second sub-pixel SP2 in the third direction DR3 may be greater than a thickness of the second organic layer OL2 of the first sub-pixel SP1 in the third direction DR3 and/or a thickness of the second organic layer OL2 of the third sub-pixel SP3 in the third direction DR3. In an embodiment, the thickness of the second organic layer OL2 of the first sub-pixel SP1 in the third direction DR3 and/or the thickness of the second organic layer OL2 of the third sub-pixel SP3 in the third direction DR3 may be about 2.2 μm or greater. In a case where the thickness of the second organic layer OL2 of the first sub-pixel SP1 in the third direction DR3 and/or the thickness of the second organic layer OL2 of the third sub-pixel SP3 in the third direction DR3 is formed to be less than about 2.2 μm, the second organic layer OL2 may not be sufficiently filled between the edge portion of the second encapsulation layer TFE2 and the first organic layer OL1 (or the partition wall SW). Accordingly, a pore, cavity or void exists between the edge portion of the second encapsulation layer TFE2 and the first organic layer OL1 (or the partition wall SW), and therefore, cracks may occur in the second encapsulation layer TFE2.

The third organic layer OL3 may be disposed over the second organic layer OL2 and the third encapsulation layer TFE3. The third organic layer OL3 may be disposed directly over the second organic layer OL2 and the third encapsulation layer TFE3. The third organic layer OL3 may completely cover the second organic layer OL2 and/or the third encapsulation layer TFE3.

In an embodiment, the first organic layer OL1 and the second organic layer Ol2 may be disposed on the partition wall SW (or the second partition wall SW2), and the edge portion of the third encapsulation layer TFE3 may be spaced apart from the second organic layer OL2. The edge portion of the third encapsulation layer TFE3 may be spaced apart from a top surface of the second organic layer OL2 in the third direction DR2. The third organic layer OL3 may be filled between the edge portion of the third encapsulation layer TFE3 and the second organic layer OL2. That is, the first to third organic layers OL1 to OL3 may be filled between the edge portion of the third encapsulation layer TFE3 and the partition wall SW (or the second partition wall SW2). Accordingly, occurrence of cracks in the third encapsulation layer TFE3 can be effectively prevented.

The third organic layer OL3 may include or be formed of a photosensitive resin composition. The third organic layer OL3 may include or be formed of a transparent photosensitive resin composition such that light emitted from the light emitting layer EM can be transmitted therethrough. The third organic layer OL3 may include or be formed of a low-temperature curable photosensitive resin composition to effectively prevent damage of the light emitting layer EM in a process of forming the third organic layer OL3. In an embodiment, for example, the third organic layer OL3 may include or be formed of a photosensitive resin composition curable at a low temperature in a range of about 70° C. to about 100° C., but the disclosure is not necessarily limited thereto. The third organic layer OL3 may include a same material as the first organic layer OL1 and/or the second organic layer OL2, but the disclosure is not necessarily limited thereto.

The third organic layer OL3 may be formed with different thicknesses in the first to third sub-pixels SP1 to SP3. That is, portions of the third organic layer OL3 in the first to third sub-pixels SP1 to SP3 may have different thicknesses from each other. In an embodiment, for example, a thickness of the third organic layer OL3 of the third sub-pixel SP3 in the third direction DR3 may be greater than a thickness of the third organic layer OL3 of the first sub-pixel SP1 in the third direction DR3 and/or a thickness of the third organic layer OL3 of the second sub-pixel SP2 in the third direction DR3. In an embodiment, the thickness of the third organic layer OL3 of the first sub-pixel SP1 in the third direction DR3 and/or the thickness of the third organic layer OL3 of the second sub-pixel SP2 in the third direction DR3 may be about 2.2 μm or greater. In a case where the thickness of the third organic layer OL3 of the first sub-pixel SP1 in the third direction DR3 and/or the thickness of the third organic layer OL3 of the second sub-pixel SP2 in the third direction DR3 is formed to be less than about 2.2 μm, the third organic layer OL3 may not be sufficiently filled between the edge portion of the third encapsulation layer TFE3 and the second organic layer OL2 (or the partition wall SW). Accordingly, a pore, cavity or void exists between the edge portion of the third encapsulation layer TFE3 and the second organic layer OL2 (or the partition wall SW), and therefore, cracks may occur in the third encapsulation layer TFE3.

An upper encapsulation layer UE may be further disposed on the organic layer OL. The upper encapsulation layer UE may be configured to cover layers thereunder, thereby effectively preventing oxygen and/or moisture from infiltrating into the layers thereunder. The upper encapsulation layer UE may include a first upper inorganic layer UI1 (or first upper encapsulation layer), an upper organic layer UO (or second upper encapsulation layer), and/or a second upper inorganic layer UI2 (or third upper encapsulation layer), which are sequentially stacked. However, the disclosure is not necessarily limited thereto. In some embodiments, at least one of the first upper inorganic layer UI1, the upper organic layer UO, and the second upper inorganic layer UI2 may be omitted.

Each of the first upper inorganic layer UI1 and the second upper inorganic layer UI2 may include silicon nitride (SiNₓ), silicon oxide (SiOₓ), silicon oxynitride (SiOₓN_{y}), or the like, but the disclosure is not necessarily limited thereto. The upper organic layer UO may include acrylic resin, epoxy resin, a phenolic resin, polyamide resin, polyimide resin, unsaturated polyester resin, polyphenylenether resin, polyphenylenesulfide resin, benzocyclobutene (BCB), or the like, but the disclosure is not necessarily limited thereto.

In accordance with embodiments, as described above, although the edge portion of the encapsulation layer TFE and the partition wall SW are spaced apart from each other in the third direction DR3, the organic layer OL is filled in an area in which the edge portion of the encapsulation layer TFE and the partition wall SW are spaced apart from each other in the third direction DR3, such that occurrence of cracks in the encapsulation layer TFE can be effectively prevented.

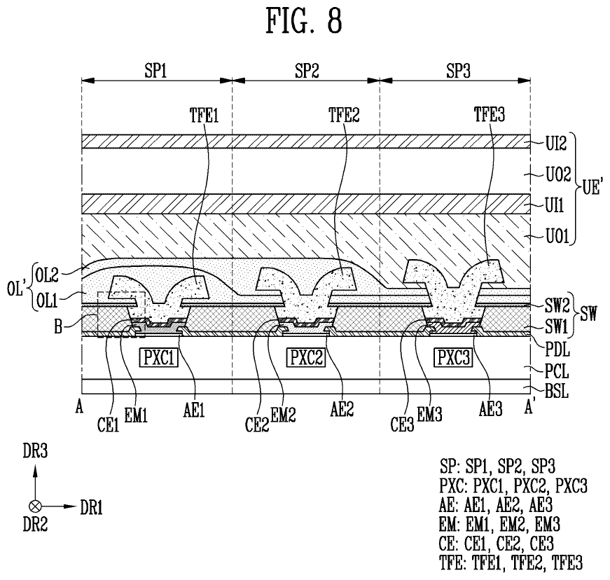

FIG. 8 is a sectional view taken along the line A-A′ shown in FIG. 5 showing another embodiment.

Referring to FIG. 8, in an embodiment, an organic layer OL′ may include a first organic layer OL1 and a second organic layer OL2. In such an embodiment, the first organic layer OL1 and the second organic layer OL2 are substantially the same as those described above with reference to FIG. 6, and therefore, any repetitive detailed descriptions thereof will be omitted.

An upper encapsulation layer UE′ may be further disposed over the organic layer OL′ (or the second organic layer OL2). The upper encapsulation layer UE′ may include a first upper organic layer UO1, a first upper inorganic layer UI1, a second upper organic layer UO2, and/or a second upper inorganic layer UI2, which are sequentially stacked. The first upper organic layer UO1, the first upper inorganic layer UI1, the second upper organic layer UO2, and/or the second upper inorganic layer UI2 may be disposed to cover layers thereunder, thereby effectively preventing oxygen and/or moisture from infiltrating into the layers thereunder.

The first upper organic layer UO1 may be disposed over the second organic layer OL2 and the third encapsulation layer TFE3. The first upper organic layer UO1 may be disposed directly over the second organic layer OL2 and the third encapsulation layer TFE3. The first upper organic layer UO1 may completely cover the second organic layer OL2 and/or the third encapsulation layer TFE3.

In an embodiment, the organic layer OL′ may be disposed on the partition wall SW (or the second partition wall SW2), and an edge portion of the first upper organic layer UO1 may be spaced apart from the organic layer OL′ (or the second organic layer OL2). The edge portion of the first upper organic layer UO1 may be spaced apart from a top surface of the organic layer OL′ (or the second organic layer OL2) in the third direction DR3. The first upper organic layer UO1 may be filled in a space between the edge portion of the third encapsulation layer TFE3 and the organic layer OL′ (or the second organic layer OL2). That is, the organic layer OL′ and the first upper organic layer UO1 may be filled in a space between the edge portion of the first upper organic layer UO1 and the partition wall SW (or the second partition wall SW2). Accordingly, occurrence of cracks in the third encapsulation layer TFE3 can be prevented.

Each of the first upper organic layer UO1 and the second upper organic layer UO2 may include acrylic resin, epoxy resin, a phenolic resin, polyamide resin, polyimide resin, unsaturated polyester resin, polyphenylenether resin, polyphenylenesulfide resin, benzocyclobutene (BCB), or the like, but the disclosure is not necessarily limited thereto. Each of the first upper organic layer UO1 and the second upper organic layer UO2 may include silicon nitride (SiNₓ), silicon oxide (SiOₓ), silicon oxynitride (SiOₓN_{y}), or the like, but the disclosure is not necessarily limited thereto.

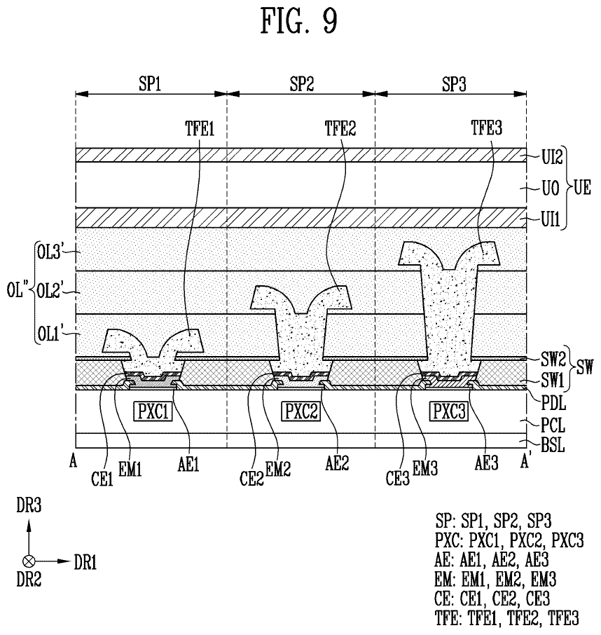

FIG. 9 is a sectional view taken along the line A-A′ shown in FIG. 5 showing another embodiment.

Referring to FIG. 9, in an embodiment, an organic layer OL″ may include a first organic layer OL1′, a second organic layer OL2′, and/or a third organic layer OL3′. In such an embodiment, a top surface of each of the first organic layer OL1′, the second organic layer OL2′, and/or the third organic layer OL3′ may be formed flat or substantially parallel with a top surface of the base layer BSL. In an embodiment, for example, each of the first organic layer OL1′, the second organic layer OL2′, and/or the third organic layer OL3′ may be formed with a uniform or constant thickness in the first to third sub-pixels SP1 to SP3. That is, the thickness of a portion of each of the first organic layer OL1′, the second organic layer OL2′, and/or the third organic layer OL3′ in each of the first to third sub-pixels SP1 to SP3 may be substantially constant. The first organic layer OL1′, the second organic layer OL2′, and/or the third organic layer OL3′ may planarize step differences due to a first encapsulation TFE1, a second encapsulation layer TFE2, and/or a third encapsulation layer TFE3, respectively. In an embodiment, the first organic layer OL1′, the second organic layer OL2′, and/or the third organic layer OL3′ may be formed through an inkjet printing process, but the disclosure is not necessarily limited thereto.

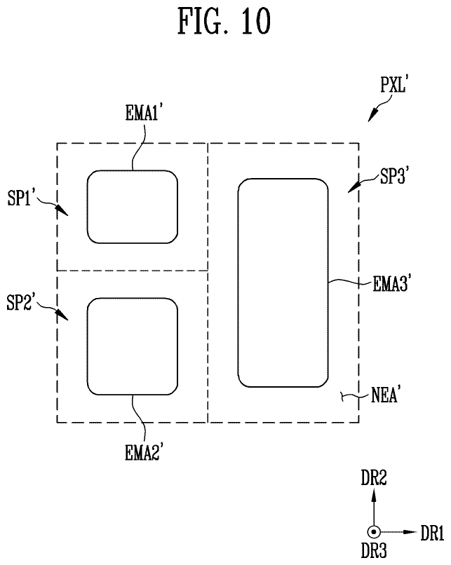

FIG. 10 is a plan view illustrating another embodiment of a pixel shown in FIG. 4.

Referring to FIG. 10, an embodiment of a pixel PXL′ may include first to third sub-pixels SP1′ to SP3′.

The first sub-pixel SP1′ may include a first emission area EMA1′ and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged in the second direction DR2 in a plan view (or when viewed in the third direction DR3). The third sub-pixel SP3′ may be disposed in the first direction DR1 with respect to each of the first and second sub-pixels SP1′ and SP2′ in a plan view.

In an embodiment, as shown in FIG. 10, the second sub-pixel SP2′ may have an area (e.g., a planar area) greater than an area of the first sub-pixel SP1′, and the third sub-pixel SP3′ may have an area greater than the area of the second sub-pixel SP2′. Accordingly, the second emission area EMA2′ may have an area greater than an area of the first emission area EMA1′, and the third emission area EMA3′ may have an area greater than the area of the second emission area EMA2′. However, embodiments are not limited thereto. In an embodiment, for example, the first and second sub-pixels SP1′ and SP2′ may substantially have a same area as each other, and the third sub-pixel SP3′ may have an area greater than the area of each of the first and second sub-pixels SP1′ and SP2′. In such embodiments, the areas of the first to third sub-pixels SP1′ to SP3′ may be variously modified in some embodiments.

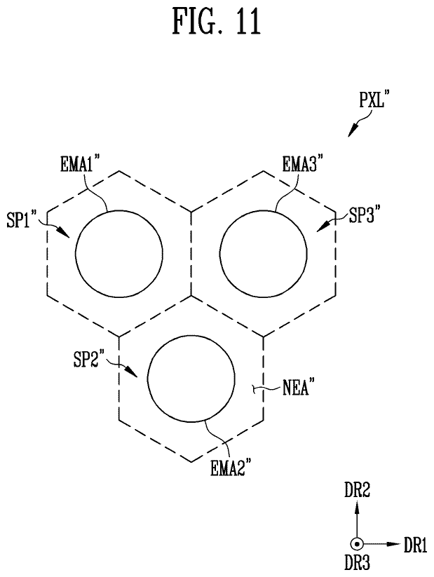

FIG. 11 is a plan view illustrating another embodiment of a pixel shown in FIG. 4.

Referring to FIG. 11, an embodiment of a pixel PXL″ may include first to third sub-pixels SP1″ to SP3″.

The first sub-pixel SP1″ may include a first emission area EMA1″ and a non-emission area NEA″ at the periphery of the first emission area EMA1″. The second sub-pixel SP2″ may include a second emission area EMA2″ and the non-emission area NEA″ at the periphery of the second emission area EMA2″. The third sub-pixel SP3″ may include a third emission area EMA3″ and the non-emission area NEA″ at the periphery of the third emission area EMA3″.

The first to third sub-pixels SP1″ to SP3″ may have polygonal shapes on a plane. In an embodiment, for example, the shapes of the first to third sub-pixels SP1″ to SP3″ may be hexagonal shapes as shown in FIG. 11.

In an embodiment, as shown in FIG. 11, the first to third emission areas EMA1″ to EMA3″ may have circular shapes in a plan view. However, embodiments are not limited thereto. In an embodiment, for example, each of the first to third emission areas EMA1″ to EMA3″ may have a polygonal shape.

In an embodiment, as shown in FIG. 11, the first and third sub-pixels SP1″ and SP3″ may be arranged in the first direction DR1 in a plan view. The second sub-pixel SP2″ may be disposed in a direction (or diagonal direction) inclined by an acute angle, based on the second direction DR2, with respect to the first sub-pixel SP1″ in a plan view.

The arrangements of the sub-pixels, which are shown in FIGS. 5, 10, and 11, are merely illustrative, and embodiments are not limited thereto. In embodiments, each pixel may include two or more sub-pixels, and the sub-pixels may be arranged in various manners. In embodiments, each of the sub-pixels may have various shapes, and an emission area EMA of the sub-pixel may have various shapes.

Hereinafter, a method of manufacturing the display device in accordance with an embodiment will be described.

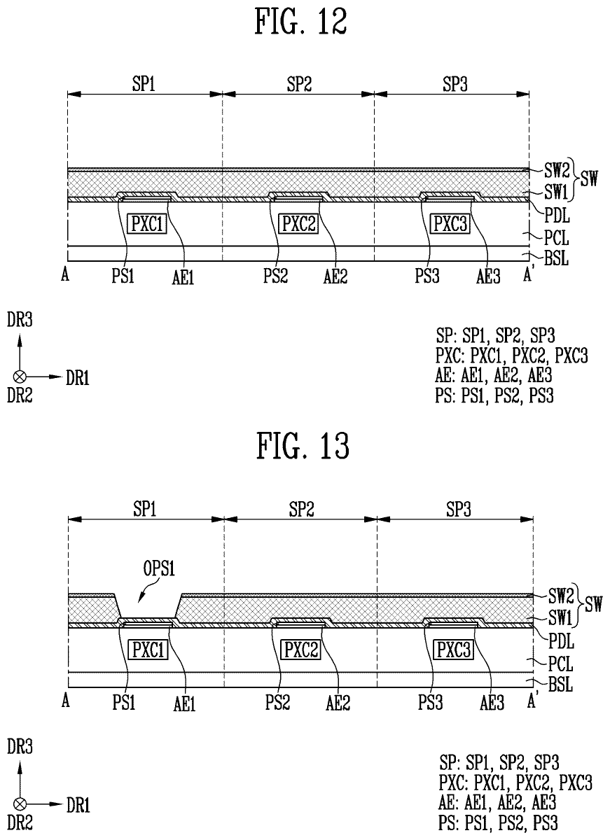

FIGS. 12 to 22 are sectional views illustrating processes of a method of manufacturing a display device in accordance with an embodiment of the disclosure. FIGS. 12 to 22 are sectional views illustrating processes of a method of manufacturing the display device shown in FIG. 6, and any repetitive detailed descriptions of the same or like elements as those described above will be omitted for convenience of description.

Referring to FIG. 12, in an embodiment of a method of manufacturing a display device, a base layer BSL is provided, on which a pixel circuit layer PCL, anode electrodes AE on the pixel circuit layer PCL, a pixel defining layer PDL on the anode electrodes AE, and a partition wall SW on the pixel defining layer PDL are formed.

The anode electrodes AE may be formed on the pixel circuit layer PCL. In some embodiments, a sacrificial layer (or protective layer) PS may be disposed on the anode electrodes AE. The sacrificial layer PS may prevent the anode electrodes AE from being damaged in a process of etching the pixel defining layer PDL and/or the partition wall SW. The sacrificial layer PS may include a first sacrificial layer PS1 formed on a first anode electrode AE1, a second sacrificial layer PS2 formed on a second anode electrode AE2, and a third sacrificial layer PS3 formed on a third anode electrode AE3.

The pixel defining layer PDL may be formed on the anode electrodes AE and/or the sacrificial layer PS. The pixel defining layer PDL may be entirely formed in first to third sub-pixels SP1 to SP3.

A first partition wall SW1 may be formed on the pixel defining layer PDL. The first partition wall SW1 may be entirely formed in the first to third sub-pixels SP1 to SP3.

A second partition wall SW2 may be formed on the first partition wall SW1. The second partition wall SW2 may be entirely formed in the first to third sub-pixels SP1 to SP3.

Referring to FIG. 13, in such an embodiment, a first partition wall opening OPS1 is formed by primarily etching (or dry etching) the partition wall SW. The first partition wall opening OPS1 may be formed in the first sub-pixel SP1. The first partition wall opening OPS1 may be formed to overlap the first anode electrode AE1.

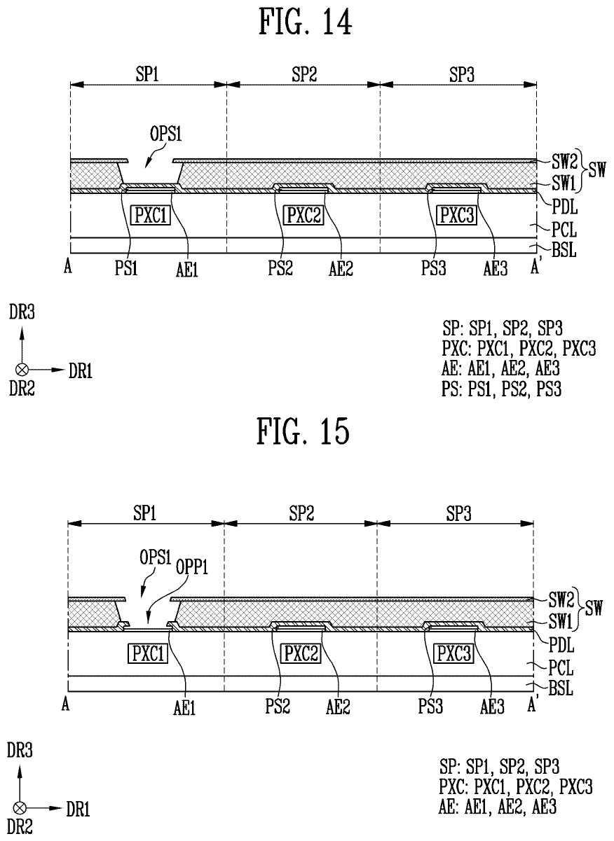

Referring to FIG. 14, in such an embodiment, a tip of the second partition wall SW2 is formed by secondarily etching (or wet etching) the partition wall SW. In an embodiment, a secondary etching process may be performed under an environment having a high etch selectivity between the first partition wall SW1 and the second partition wall SW2. In an embodiment, for example, as an etch rate of the first partition wall SW1 with respect to an etchant is greater than an etch rate of the second partition wall SW2 with respect to the etchant, the first partition wall SW1 may be selectively etched. Accordingly, a width of the second partition wall SW2 is formed greater than a width of the first partition wall SW1, and therefore, the tip of the second partition wall SW1, which protrudes from the first partition wall SW1, may be formed. In an embodiment, for example, the secondarily etched partition wall SW may have an undercut shape on a section.

Referring to FIG. 15, in such an embodiment, a first light emitting opening OPP1 is formed by etching the pixel defining layer PDL. The first light emitting opening OPP1 may be formed by etching a portion of the pixel defining layer exposed by the first partition wall opening OPS1. The first light emitting opening OPP1 may overlap the first partition wall opening OPS1 in the third direction DR3.

The first light emitting opening OPP1 may be formed in the first sub-pixel SP1. The first light emitting opening OPP1 may expose the first anode electrode AE1. The first sacrificial layer PS1 may be removed in a process of forming the first light emitting opening OPP1, but the disclosure is not necessarily limited thereto.

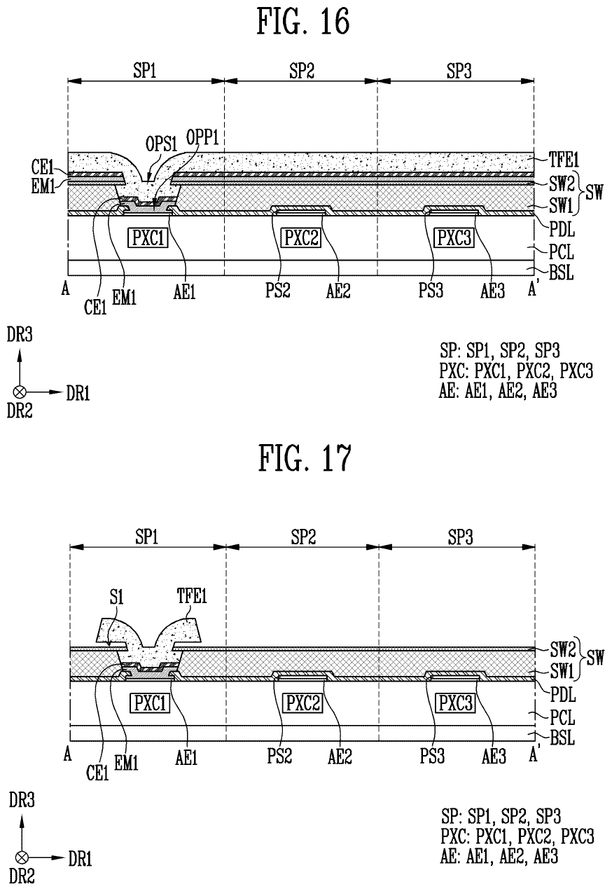

Referring to FIG. 16, in such an embodiment, a first light emitting layer EM1, a first cathode electrode CE1, and a first encapsulation layer TFE1 are formed on the first anode electrode AE1.

The first light emitting layer EM1 may be entirely formed in the first to third sub-pixels SP1 to SP3. The first light emitting layer EM1 may be separated by a tip structure of the partition wall SW. Accordingly, one area of the first light emitting layer EM1 may be formed in the first light emitting opening OPP1 and/or the first partition wall opening OPS1. The one area (or portion) of the first light emitting layer EM1 may be formed on the first anode electrode AE1 exposed by the first light emitting opening OPP1 and/or the first partition wall opening OPS1. Another area (or portion) of the first light emitting layer EM1 may be formed on the partition wall SW (or the second partition wall SW2). The another area of the first light emitting layer EM1 may be removed in a subsequent process.

The first cathode electrode CE1 may be formed on the first light emitting layer EM1. The first cathode electrode CE1 may be entirely formed in the first to third sub-pixels SP1 to SP3. The first cathode electrode CE1 may be separated by the tip structure of the partition wall SW. Accordingly, one area of the first cathode electrode CE1 may be formed in the first partition wall opening OPS1. Another area of the cathode electrode CE1 may be formed on the partition wall SW. The another area of the first cathode electrode CE1 may be removed in a subsequent process.

The first encapsulation layer TFE1 may be formed on the first cathode electrode CE1. The first encapsulation layer TFE1 may be formed in the first partition wall opening OPS1. In an embodiment, the first encapsulation layer TFE1 may be entirely formed in the first to third sub-pixels SP1 to SP3.

Referring to FIG. 17, in such an embodiment, the first encapsulation layer TFE is etched. In an embodiment, for example, the first encapsulation layer TFE1 except the portion of the first encapsulation layer TFE1 formed on the first light emitting layer EM1 may be etched and removed. In a process of etching the first encapsulation layer TFE1, layers (e.g., the another area of the first light emitting layer EM1 and/or the another area of the first cathode electrode CE1) formed between the first encapsulation layer TFE1 and the partition wall SW (or the second partition wall SW2) may be removed together with the first encapsulation layer TFE1. Accordingly, as shown in FIG. 17, a space S1 may be formed between an edge portion of the first encapsulation layer TFE1 and the partition wall SW (or the second partition wall).

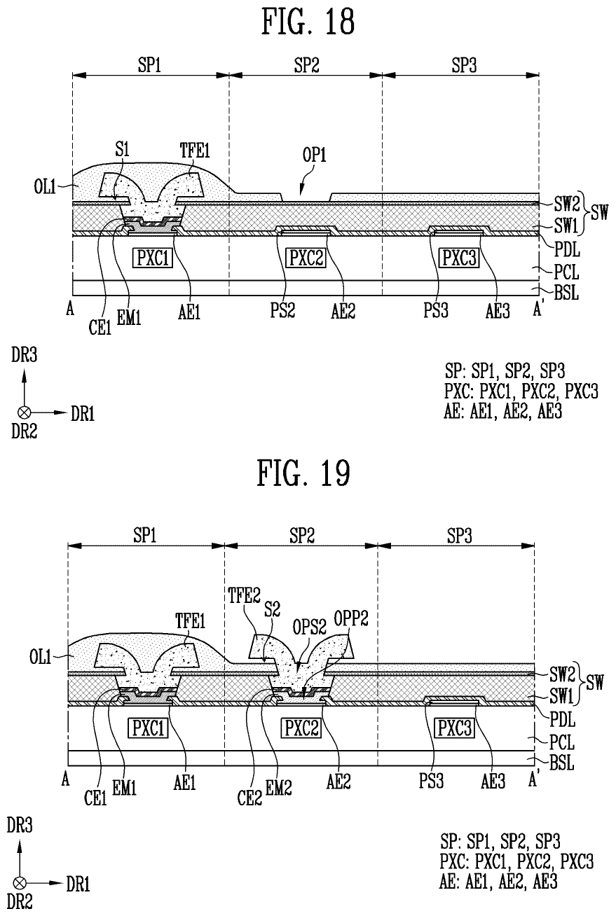

Referring to FIG. 18, in such an embodiment, a first organic layer OI1 is formed over (or to cover) the partition wall SW and the first encapsulation layer TFE1. The first organic layer OL1 may be formed of a low-temperature curable photosensitive resin composition. In an embodiment, for example, the first organic layer OL1 may be formed of a photosensitive resin composition curable at a low temperature in a range of about 70° C. to about 100° C., but the disclosure is not necessarily limited thereto.

The first organic layer OL1 may be filled in the space S1 between the edge portion of the first encapsulation layer TFE1 and the partition wall (or the second partition wall SW2). The first organic layer OL1 may be completely filled in the space S1 formed between the edge portion of the first encapsulation layer TFE1 and the partition wall (or the second partition wall SW2). Accordingly, any pore, cavity or void may not exist between the edge portion of the first encapsulation layer TFE1 and the partition wall (or the second partition wall SW2), but the disclosure is not necessarily limited thereto. In such an embodiment, as described above, the first organic layer OL1 is filled in a space between the edge portion of the first encapsulation layer TFE1 and the partition wall SW, such that occurrence of cracks in the first encapsulation layer TFE1 can be effectively prevented even when the edge portion of the first encapsulation layer TFE1 and the partition wall SW are spaced apart from each other.

In such an embodiment, as shown in FIG. 18, a first opening OP1 overlapping the second sub-pixel SP2 (or the second anode electrode AE2) may be formed in the first organic layer OL1. The first organic layer OL1 may serve as a photoresist pattern. That is, the partition wall SW may be patterned using the first organic layer OL1. As such, the encapsulation layer TFE patterns the partition wall SW, using an organic layer OL filled in a space spaced apart from a lower layer of an encapsulation layer TFE, so that the number of masks to use during manufacturing processes can be decreased, thereby simplifying manufacturing processes.

Referring to FIG. 19, in such an embodiment, a second partition wall opening OPS2 is formed by etching the partition wall SW. As described above, the partition wall SW may be etched using the first organic layer OL1. In an embodiment, for example, the second partition wall opening OPS2 of the partition wall SW may be formed by etching an area overlapping the first opening OP1 of the first organic layer OL1. A tip of the second partition wall SW2 may be formed by primarily etching (or dry etching) and then secondarily etching (or wet etching) the partition wall SW. Primary and secondary etching processes of the partition wall SW are substantially the same as those described above with reference to FIGS. 13 and 14, and therefore, any repetitive detailed descriptions thereof will be omitted.

In such an embodiment, a second light emitting opening OPP2 is formed by etching the pixel defining layer PDL, and a second light emitting layer EM2, a second cathode electrode CE2, and a second encapsulation layer TFE2 are formed on the second anode electrode AE2.

The second light emitting opening OPP2 may be formed by etching the pixel defining layer PDL exposed by the second partition wall opening OPS2. The second light emitting opening OPP2 may overlap the second partition wall opening OPS2 in the third direction DR3.

The second light emitting opening OPP2 may be formed in the second sub-pixel SP2. The second light emitting opening OPP2 may expose the second anode electrode AE2. The second sacrificial layer PS2 may be removed in a process of forming the second light emitting opening OPP2, but the disclosure is not necessarily limited thereto.

The second light emitting layer EM2 may be entirely formed in the first to third sub-pixels SP1 to SP3. The second light emitting layer EM2 may be separated by a tip structure of the partition wall SW. One area of the second light emitting layer EM2 may be formed in the second light emitting opening OPP2 and/or the second partition wall opening OPS2. The one area of the second light emitting layer EM2 may be formed on the second anode electrode AE2 exposed by the second light emitting opening OPP2 and/or the second partition wall opening OPS2. Another area of the second light emitting layer EM2 may be formed on the first organic layer OL1. The another area of the second light emitting layer EM2 may be removed in a subsequent process.

The second cathode electrode CE2 may be formed on the second light emitting layer EM2. The second cathode electrode CE2 may be entirely formed in the first to third sub-pixels SP1 to SP3. The second cathode electrode CE2 may be separated by the tip structure of the partition wall SW. Accordingly, one area of the second cathode electrode CE2 may be formed in the second partition wall opening OPS2. Another area of the second cathode electrode CE2 may be formed on the first organic layer OL1. The another area of the second cathode electrode CE2 may be removed in a subsequent process.

The second encapsulation layer TFE2 may be formed on the second cathode electrode CE2. The second encapsulation layer TFE2 may be formed in the second partition wall opening OPS2. In an embodiment, the second encapsulation layer TFE2 may be entirely formed in the first to third sub-pixels SP1 to SP3.

In such an embodiment, in a process of etching the second encapsulation layer TFE2, layers (e.g., the another area of the second light emitting layer EM2 and/or the another area of the second cathode electrode CE2) formed between the second encapsulation layer TFE2 and the first organic layer OL1 may be removed together with the second encapsulation layer TFE2. Accordingly, as shown in FIG. 19, a space S2 may be formed between an edge portion of the second encapsulation layer TFE2 and the first organic layer OL1.

In addition, processes of forming the second light emitting opening OPP2 of the pixel defining layer PDL, and forming the second light emitting layer EM2, the second cathode electrode CE2, and the second encapsulation layer TFE2 on the second anode electrode AE2 are similar to the processes of forming the first light emitting opening OPP1 of the pixel defining layer PDL, and forming the first light emitting layer EM1, the first cathode electrode CE1, and the first encapsulation layer TFE1 on the first anode electrode AE1 (see FIGS. 15 and 16), and therefore, any repetitive detailed descriptions thereof will be omitted.

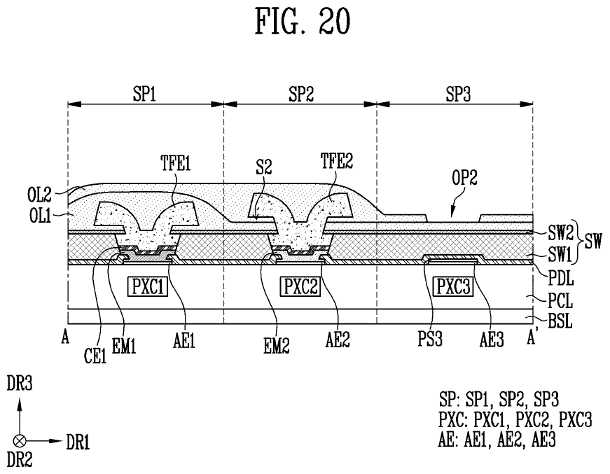

Referring to FIG. 20, in such an embodiment, a second organic layer OL2 is formed over (or to cover) the first organic layer OL1 and the second encapsulation layer TFE2. The second organic layer OL2 may be formed of a low-temperature curable photosensitive resin composition. In an embodiment, for example, the second organic layer OL2 may be formed of a photosensitive resin composition curable at a low temperature in a range of about 70° C. to about 100° C., but the disclosure is not necessarily limited thereto. The second organic layer OL2 may be formed of a same material as the first organic layer OL1, but the disclosure is not necessarily limited thereto.

The second organic layer OL2 may be filled in the space S2 between the edge portion of the second encapsulation layer TFE2 and the first organic layer OL1. The second organic layer OL2 may be completely filled in the space S2 formed between the edge portion of the second encapsulation layer TFE2 and the first organic layer OL1. Accordingly, any pore, cavity or void may not exist between the edge portion of the second encapsulation layer TFE and the first organic layer OL1, but the disclosure is not necessarily limited thereto. In such an embodiment, as described above, the second organic layer OL2 is filled between the edge portion of the second encapsulation layer TFE2 and the first organic layer OL1, such that occurrence of cracks in the second encapsulation layer TFE2 can be effectively prevented even when the edge portion of the second encapsulation layer TFE2 and the first organic layer OL1.

The second organic layer OL2 may include a second opening OP2 overlapping the third sub-pixel SP3 (or the third anode electrode AE3). The second organic layer OL2 may serve as a photoresist pattern. That is, the partition wall SW may be patterned using the second organic layer OL2. As such, the encapsulation layer TFE patterns the partition wall SW, using the organic layer OL filled in a space spaced apart from a lower layer, such that the number of masks to use during manufacturing processes can be decreased, thereby simplifying manufacturing processes, as described above.

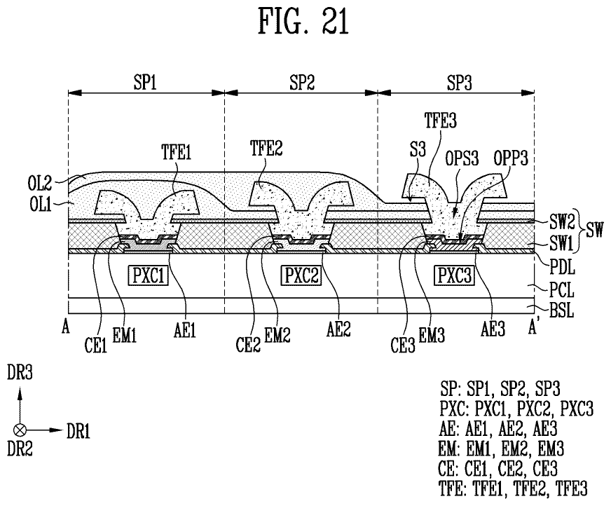

Referring to FIG. 21, in such an embodiment, a third partition wall opening OPS3 is formed by etching the partition wall SW. As described above, the partition wall SW may be etched using the second organic layer OL2. In an embodiment, for example, the third partition wall OPS3 of the partition wall SW may be formed by etching an area overlapping with the second opening OP2 of the second organic layer OL2. A tip of the second partition wall SW2 may be formed by primarily etching (or dry etching) and then secondarily etching (or wet etching) the partition wall SW. Primary and secondary etching processes of the partition wall SW are substantially the same as those described above with reference to FIGS. 13 and 14, and therefore, any repetitive detailed descriptions thereof will be omitted.

In such an embodiment, a third light emitting opening OPP3 is formed by etching the pixel defining layer PDL, and a third light emitting layer EM3, a third cathode electrode CE3, and a third encapsulation layer TFE3 are formed on the third anode electrode AE3.

The third light emitting opening OPP3 may be formed by etching the pixel defining layer PDL exposed by the third partition wall opening OPS3. The third light emitting opening OPP3 may overlap the third partition wall opening OPS3 in the third direction DR3.

The third light emitting opening OPP3 may be formed in the third sub-pixel SP3. The third light emitting opening OPP3 may expose the third anode electrode AE3. The third sacrificial layer PS3 may be removed in a process of forming the third light emitting opening OPP3, but the disclosure is not necessarily limited thereto.

The third light emitting layer EM3 may be entirely formed in the first to third sub-pixels SP1 to SP3. The third light emitting layer EM3 may be separated by a tip structure of the partition wall SW. Accordingly, one area of the third light emitting layer EM3 may be formed in the third light emitting opening OPP3 and/or the third partition wall opening OPS3. The one area of the third light emitting layer EM3 may be formed on the third anode electrode AE3 exposed by the third light emitting opening OPP3 and/or the third partition wall opening OPS3. Another area of the third light emitting layer EM3 may be formed on the second organic layer OL2. The another area of the third light emitting layer EM3 may be removed in a subsequent process.

The third cathode electrode CE3 may be formed on the third light emitting layer EM3. The third cathode electrode CE3 may be entirely formed in the first to third sub-pixels SP1 to SP3. The third cathode electrode CE3 may be separated by the tip structure of the partition wall SW. Accordingly, one area of the third cathode electrode CE3 may be formed in the third partition wall opening OPS3. Another area of the third cathode electrode CE3 may be formed on the second organic layer OL2. The another area of the third cathode electrode CE3 may be removed in a subsequent process.

The third encapsulation layer TFE3 may be formed on the third cathode electrode CE3. The third encapsulation layer TFE3 may be formed in the third partition wall opening OPS3. In an embodiment, the third encapsulation layer TFE3 may be entirely formed in the first to third sub-pixels SP1 to SP3.

Processes of forming the third light emitting opening OPP3 of the pixel defining layer PDL, and forming the third light emitting layer EM3, the third cathode electrode CE3, and the third encapsulation layer TFE3 on the third anode electrode AE3 are similar to the processes of forming the first light emitting opening OPP1 of the pixel defining layer PDL, and forming the first light emitting layer EM1, the first cathode electrode CE1, and the first encapsulation layer TFE1 on the first anode electrode AE1, and therefore, overlapping descriptions will be omitted.

In such an embodiment, in a process of etching the third encapsulation layer TFE3, layers (e.g., the another area of the third light emitting layer EM3 and/or the another area of the third cathode electrode CE3) formed between the third encapsulation layer TFE3 and the second organic layer OL2 may be removed together with the third encapsulation layer TFE3. Accordingly, as shown in FIG. 21, a space S3 may be formed between an edge portion of the third encapsulation layer TFE3 and the second organic layer OL2.

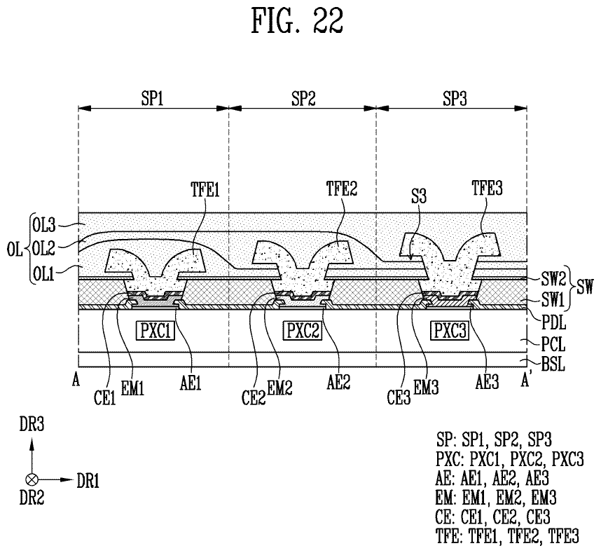

Referring to FIG. 22, in such an embodiment, a third organic layer OL3 is formed over (or to cover) the second organic layer OL2 and the third encapsulation layer TFE3. The third organic layer OL3 may be formed of a low-temperature curable photosensitive resin composition. In an embodiment, for example, the third organic layer OL3 may be formed of a photosensitive resin composition curable at a low temperature of 70° C. to 100° C., but the disclosure is not necessarily limited thereto. The third organic layer OL3 may be formed of a same material as the second organic layer and/or the first organic layer OL1, but the disclosure is not necessarily limited thereto.

The third organic layer OL3 may be filled in a space S3 formed between an edge portion of the third encapsulation layer TFE3 and the second organic layer OL2. The third organic layer OL3 may be completely filled in a space S3 formed between the edge portion of the third encapsulation layer TFE3 and the second organic layer OL2. Accordingly, any pore, cavity or void may not exist between the edge portion of the third encapsulation layer TFE3 and the second organic layer OL2, but the disclosure is not necessarily limited thereto. As such, when the third organic layer OL3 is filled between the edge portion of the third encapsulation layer TFE3 and the second organic layer OL2, occurrence of cracks in the third encapsulation layer TFE3 can be prevented even when the edge portion of the third encapsulation layer TFE3 and the second organic layer OL2 are spaced apart from each other.

In such an embodiment, an upper encapsulation layer (UE shown in FIG. 6) is formed on the organic layer OL including the first organic layer OL1, the second organic layer OL2, and the third organic layer OL3, thereby completing the display device shown in FIG. 6.

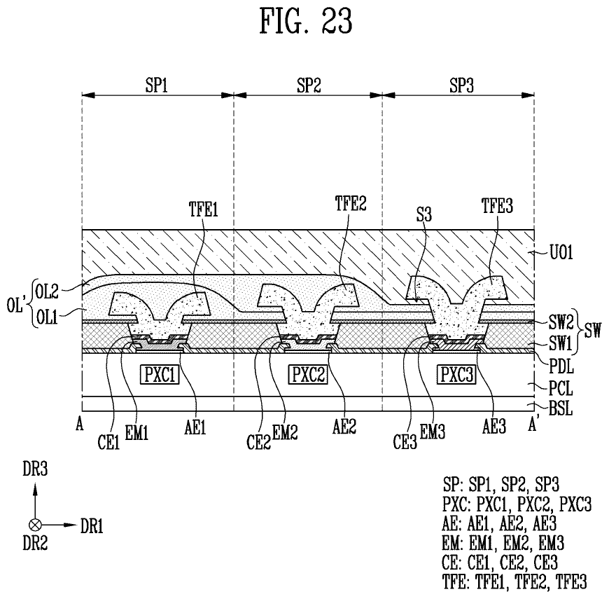

FIG. 23 is a sectional view illustrating processes of a method of manufacturing a display device in accordance with an embodiment of the disclosure. FIG. 23 is a sectional view illustrating processes for manufacturing the display device shown in FIG. 8, and any repetitive detailed descriptions of the same or like elements as those described above will be omitted for convenience of description.

Referring to FIG. 23, a first upper organic layer UO1 is formed over (or to cover) an organic layer OL′ (or a second organic layer OL2) and a third encapsulation layer TFE3. The first upper organic layer UO1 may be configured to prevent oxygen and/or moisture from infiltrating into layers thereunder by covering the layers thereunder. In addition, processes up to a process of forming the third encapsulation layer TFE3 are substantially the same as those described above with reference to FIGS. 12 to 21, and therefore, any repetitive detailed descriptions thereof will be omitted.

The first upper organic layer UO1 may be formed of acrylic resin, epoxy resin, a phenolic resin, polyamide resin, polyimide resin, unsaturated polyester resin, polyphenylenether resin, polyphenylenesulfide resin, benzocyclobutene (BCB), or the like, but the disclosure is not necessarily limited thereto.

The first upper organic layer UO1 may be filled in a space S3 formed between an edge portion of the third encapsulation layer TFE3 and the second organic layer OL2. The first upper organic layer UO1 may be completely filled in a space S3 formed between the edge portion of the third encapsulation layer TFE3 and the second organic layer OL2. Accordingly, any pore, cavity or void may not exist between the edge portion of the third encapsulation layer TFE3 and the second organic layer OL2, but the disclosure is not necessarily limited thereto. In such an embodiment, the first upper organic layer UO1 is filled between the edge portion of the third encapsulation layer TFE3 and the second organic layer OL2, such that occurrence of cracks in the third encapsulation layer TFE3 can be effectively prevented even when the edge portion of the third encapsulation layer TFE3 and the second organic layer OL2 are spaced apart from each other.

In such an embodiment, a first upper inorganic layer (UI1 shown in FIG. 8), a second upper inorganic layer (UO2 shown in FIG. 8), and a second upper inorganic layer (UI2 shown in FIG. 8) are formed on the first upper organic layer UO1, thereby completing the display device shown in FIG. 8.

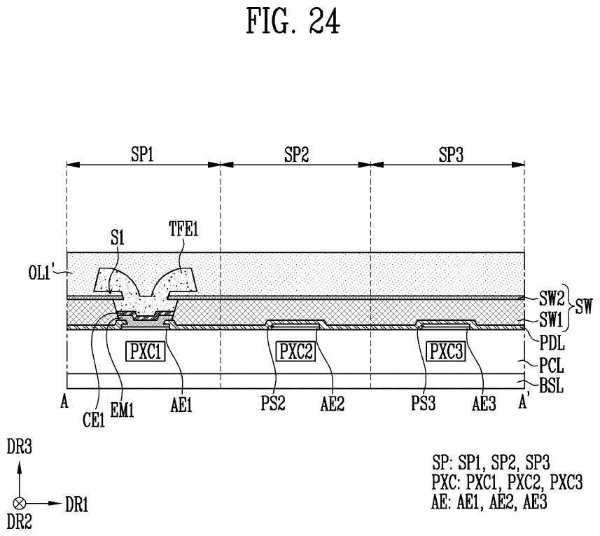

FIGS. 24 to 30 are sectional views illustrating processes of a method of manufacturing a display device in accordance with an embodiment of the disclosure. FIGS. 24 to 30 are sectional views illustrating processes for manufacturing the display device shown in FIG. 9, and any repetitive detailed descriptions of the same or like elements as those described above will be omitted for convenience of description.

Referring to FIG. 24, a first organic layer OL1′ is formed over (or to cover) a partition wall SW and a first encapsulation layer TFE1. Processes up to a process of forming the first encapsulation layer TFE1 are substantially the same as those described above with reference to FIGS. 12 to 17, and therefore, any repetitive detailed descriptions thereof will be omitted.

In an embodiment, as shown in FIG. 24, a top surface of the first organic layer OL1′ may be formed flat. In an embodiment, for example, the first organic layer OL1′ may be formed with a uniform thickness in first to third sub-pixels SP1 to SP3. The first organic layer OL1′ may planarize a step difference due to the first encapsulation layer TFE1. In an embodiment, the first organic layer OL1′ may be formed through an inkjet printing process, but the disclosure is not necessarily limited thereto.

The first organic layer OL1′ may be filled in a space S1 formed between an edge portion of the first encapsulation layer TFE1 and the partition wall SW (or a second partition wall SW2). The first organic layer OL1′ may be completely filled in the space S1 formed between the edge portion of the first encapsulation layer TFE1 and the partition wall SW (or the second partition wall SW2). Accordingly, any pore, cavity or void may not exist between the edge portion of the first encapsulation layer TFE1 and the partition wall SW (or the second partition wall SW2), but the disclosure is not necessarily limited thereto. In such an embodiment, the first organic layer OL1′ is filled between the edge portion of the first encapsulation layer TFE1 and the partition wall SW, such that occurrence of cracks in the first encapsulation layer TFE can be effectively prevented even when the edge portion of the first encapsulation layer TFE1 and the partition wall SW are spaced apart from each other, as described above.

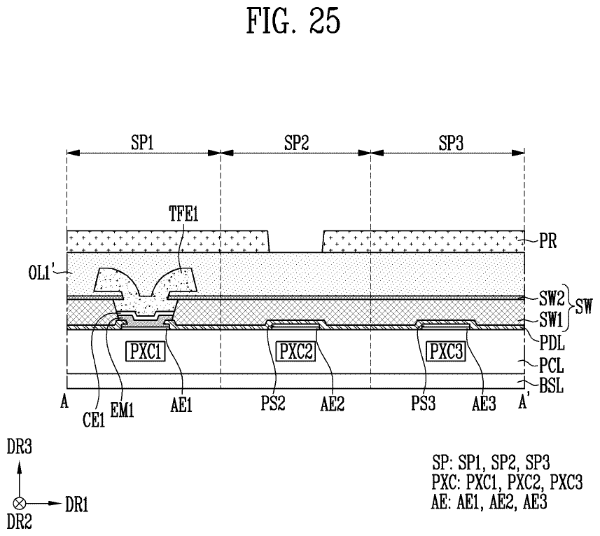

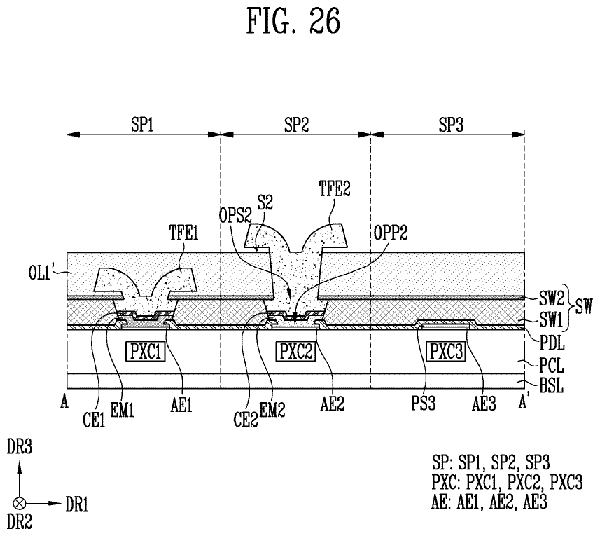

Referring to FIGS. 25 and 26, in such an embodiment, a photoresist pattern PR is formed on the first organic layer OL1′, and a second partition wall opening OPS2 is formed by etching the partition wall SW. In such an embodiment, a second light emitting opening OPP2 is formed by etching a pixel defining layer PDL, and a second light emitting layer EM2, a second cathode electrode CE2, and a second encapsulation layer TFE2 are formed on a second anode electrode AE2. In a process of etching the second encapsulation layer TFE2, layers (e.g., another area of the second light emitting layer EM2 and/or another area of the second cathode electrode CE2) formed between the second encapsulation layer TFE2 and the first organic layer OL1′ may be removed together with the second encapsulation layer TFE2. Accordingly, a second space S2 may be formed between an edge portion of the second encapsulation layer TFE2 and the first organic layer OL1′.

Processes of forming the second partition wall opening OPS2 of the partition wall SW, forming the second light emitting opening OPP2 of the pixel defining layer PDL, and forming the second light emitting layer EM2, the second cathode electrode CE2, and the second encapsulation layer TFE2 on the second anode electrode AE2 are substantially the same as those described with reference to FIG. 19, and therefore, any repetitive detailed descriptions thereof will be omitted.

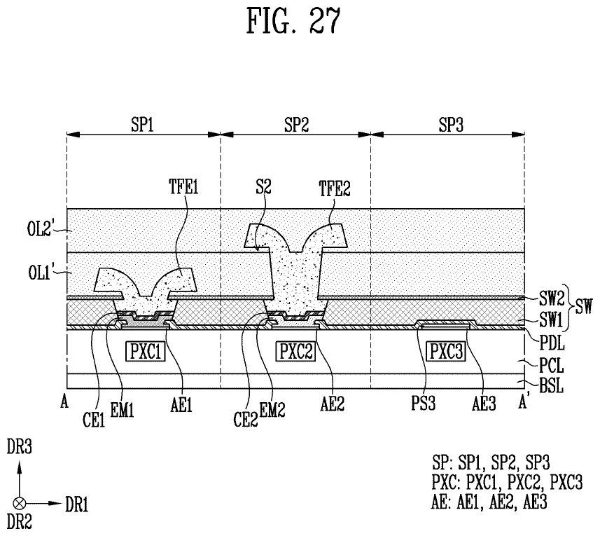

Referring to FIG. 27, a second organic layer OL2′ is formed over (or to cover) the first organic layer OL1′ and the second encapsulation layer TFE2. A top surface of the second organic layer OL2′ may be formed flat. In an embodiment, for example, the second organic layer OL2′ may be formed with a uniform thickness in the first to third sub-pixels SP1 to SP3. The second organic layer OL2′ may planarize a step difference due to the second encapsulation layer TFE2. In an embodiment, the second organic layer OL2′ may be formed through an inkjet printing process, but the disclosure is not necessarily limited thereto.

The second organic layer OL2′ may be filled in the space S2 formed between the edge portion of the second encapsulation layer TFE2 and the first organic layer OL1′. The second organic layer OL2 may be completely filled in the space S2 formed between the edge portion of the second encapsulation layer TFE2 and the first organic layer OL1′. Accordingly, any pore, cavity or void may not exist between the edge portion of the second encapsulation layer TFE2 and the first organic layer OL1′, but the disclosure is not necessarily limited thereto. In such an embodiment, the second organic layer OL2′ is filled between the edge portion of the second encapsulation layer TFE2 and the first organic layer OL1′, such that occurrence of cracks in the second encapsulation layer TFE2 can be effectively prevented even when the edge portion of the second encapsulation layer TFE2 and the first organic layer OL1′ are spaced apart from each other, as described above.

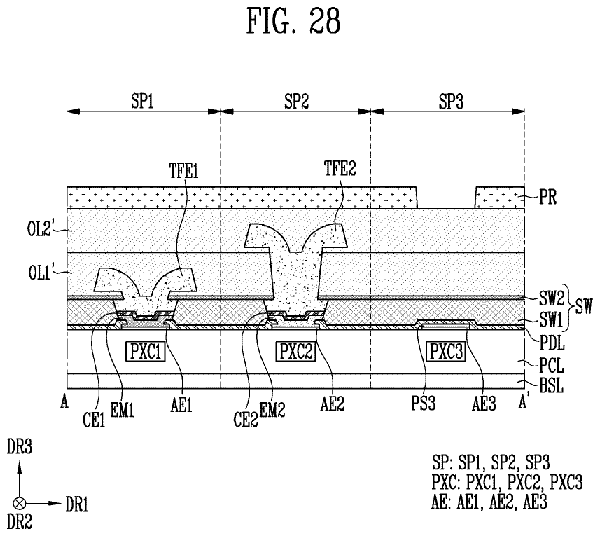

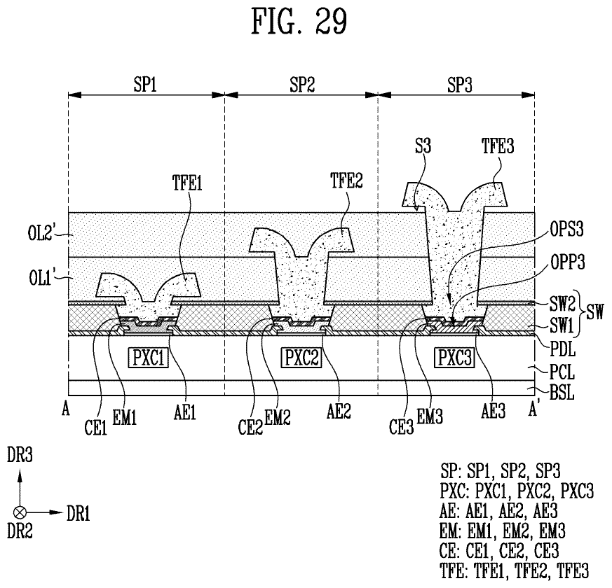

Referring to FIGS. 28 and 29, in such an embodiment, a photoresist pattern PR is formed on the second organic layer OL2′, and a third partition wall opening OPS3 is formed by etching the partition wall SW. In such an embodiment, a third light emitting opening OPP3 is formed by etching the pixel defining layer PDL, and a third light emitting layer EM3, a third cathode electrode CE3, and a third encapsulation layer TFE3 are formed in a third anode electrode AE3. In a process of etching the third encapsulation layer TFE3, layers (e.g., another area of the third light emitting layer EM3 and/or another area of the third cathode electrode CE3) formed between the third encapsulation layer TFE3 and the second organic layer OL2′ may be removed together with the third encapsulation layer TFE3. Accordingly, as shown in FIG. 29, a space S3 may be formed between an edge portion of the third encapsulation layer TFE3 and the second organic layer OL2′.

Processes of forming the third partition wall opening OPS3 of the partition wall SW, forming the third light emitting opening OPP3 of the pixel defining layer PDL, and forming the third light emitting layer EM3, the third cathode electrode CE3, and the third encapsulation layer TFE3 on the third cathode electrode AE3 are substantially the same as those described above with reference to FIG. 21, and therefore, any repetitive detailed descriptions thereof will be omitted.

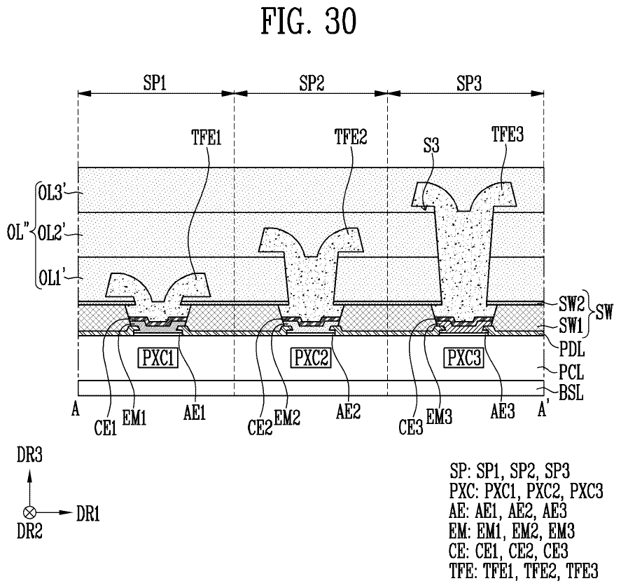

Referring to FIG. 30, in such an embodiment, a third organic layer OL3′ is formed over (or to cover) the second organic layer OL2′ and the third encapsulation layer TFE3. The third organic layer OL3′ may be formed flat. In an embodiment, for example, the third organic layer OL3′ may be formed with a uniform thickness in the first to third sub-pixels SP1 to SP3. The third organic layer OL3′ may planarize a step difference due to the third encapsulation layer TFE3. In an embodiment, the third organic layer OL3′ may be formed through an inkjet printing process, but the disclosure is not necessarily limited thereto.

The third organic layer OL3′ may be filled in the space S3 formed between the edge portion of the third encapsulation layer TFE3 and the second organic layer OL2′. The third organic layer OL3′ may be completely filled in the space S3 formed between the edge portion of the third encapsulation layer TFE3 and the second organic layer OL2′. Accordingly, any pore, cavity or void may not exist between the edge portion of the third encapsulation layer TFE3 and the second organic layer OL2′, but the disclosure is not necessarily limited thereto. In such an embodiment, the third organic layer OL3′ is filled between the edge portion of the third encapsulation layer TFE3 and the second organic layer OL2′, such that occurrence of cracks in the third encapsulation layer TFE3 can be effectively prevented even when the edge portion of the third encapsulation layer TFE3 and the second organic layer OL2′ are spaced apart from each other, which has been described above.

In such an embodiment, an upper encapsulation layer (UE shown in FIG. 9) is formed on an organic layer OL″ including the first organic layer OL1′, the second organic layer OL2′, and the third organic layer OL3′, thereby completing the display device shown in FIG. 9.

In accordance with embodiments of the disclosure, an organic layer is filled in a space in which an encapsulation layer is spaced apart from a lower layer, such that occurrence of cracks in the encapsulation can be effectively prevented. In such embodiments, a partition wall is patterned using the organic layer, so that the number of masks to use during manufacturing processes can be decreased, thereby simplifying manufacturing processes.

A display device according to an embodiment is applicable to various types of electronic devices. In an embodiment, an electronic device includes the above-described display device and may further include other modules or devices having additional functions in addition to the display device.

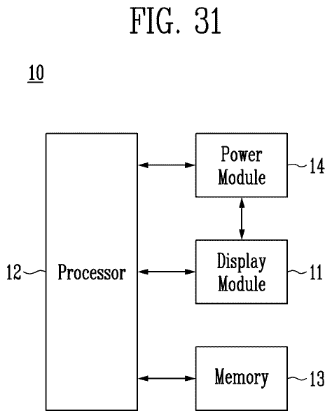

FIG. 31 is a block diagram of an electronic device according to an embodiment. Referring to FIG. 31, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

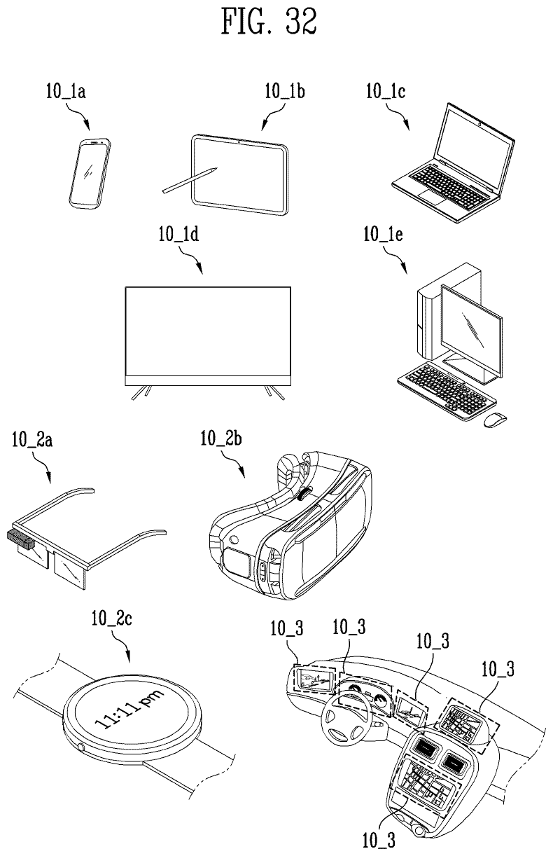

FIG. 32 shows schematic views of various embodiments of an electronic device.

Referring to FIG. 32, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first electrode;
a pixel defining layer on the first electrode, wherein a light emitting opening is defined through the pixel defining layer;
a partition wall on the pixel defining layer, wherein a partition wall opening overlapping the light emitting opening is defined through the partition wall;
a light emitting layer in the light emitting opening and the partition wall opening;
a second electrode on the light emitting layer;
an encapsulation layer on the second electrode and the partition wall; and
an organic layer covering the encapsulation layer,
wherein an edge portion of the encapsulation layer is spaced apart from the partition wall, and
wherein the organic layer is filled in a space between the edge portion of the encapsulation layer and the partition wall.

2. The display device of claim 1, wherein any cavity or void does not exist in the space between the edge portion of the encapsulation layer and the partition wall.

3. The display device of claim 1, further comprising an upper encapsulation layer on the organic layer.

4. The display device of claim 3, wherein the upper encapsulation layer includes a first upper encapsulation layer, a second upper encapsulation layer on the first upper encapsulation layer, and a third upper encapsulation layer on the second upper encapsulation layer.

5. The display device of claim 1, wherein the light emitting layer includes a first light emitting layer, a second light emitting layer, and a third light emitting layer, which emit lights of different colors, and
wherein the encapsulation layer includes a first encapsulation layer on the first light emitting layer, a second encapsulation layer on the second light emitting layer, and a third encapsulation layer on the third light emitting layer.

6. The display device of claim 5, wherein an edge portion of each of the first encapsulation layer, the second encapsulation layer, and the third encapsulation layer is spaced apart from the partition wall, and
wherein the organic layer includes a first organic layer covering the partition wall and the first encapsulation layer, a second organic layer covering the first organic layer and the second encapsulation layer, and a third organic layer covering the second organic layer and the third encapsulation layer.

7. The display device of claim 6, wherein the first organic layer is filled in a space between the edge portion of the first encapsulation layer and the partition wall.

8. The display device of claim 6, wherein the edge portion of the second encapsulation layer is spaced apart from the first organic layer, and
the edge portion of the third encapsulation layer is spaced apart from the second organic layer.

9. The display device of claim 8, wherein the second organic layer is filled in a space between the edge portion of the second encapsulation layer and the first organic layer.

10. The display device of claim 8, wherein the third organic layer is filled in a space between the edge portion of the third encapsulation layer and the second organic layer.

11. The display device of claim 6, wherein an opening overlapping the second light emitting layer is defined through the first organic layer, and
wherein the second encapsulation layer is in the opening of the first organic layer.

12. The display device of claim 6, wherein an opening overlapping the third light emitting layer is defined through the second organic layer, and
wherein the third encapsulation layer is in the opening of the second organic layer.

13. The display device of claim 12, wherein an opening overlapping the opening of the second organic layer is defined through the first organic layer, and
wherein the third encapsulation layer is in the opening of the first organic layer.

14. A method of manufacturing a display device, the method comprising:
providing a base layer on which a first electrode, a pixel defining layer on the first electrode, and a partition wall on the pixel defining layer are formed;
forming a first partition wall opening by etching the partition wall;
forming a first light emitting opening overlapping the first partition wall opening by etching the pixel defining layer;
forming a first light emitting layer in the first light emitting opening and the first partition wall opening;
forming a first encapsulation layer on the first light emitting layer and the partition wall; and
forming a first organic layer to cover the first encapsulation layer,
wherein the first organic layer is filled in a space formed between an edge portion of the first encapsulation layer and the partition wall.

15. The method of claim 14, wherein the first organic layer includes a low-temperature curable photosensitive resin composition.

16. The method of claim 14, further comprising:
forming a second partition wall opening by etching the partition wall through an opening of the first organic layer;
forming a second light emitting opening overlapping the second partition wall opening by etching the pixel defining layer; and
forming a second light emitting layer in the second light emitting opening and the second partition wall opening.

17. The method of claim 16, further comprising:
forming a second encapsulation layer on the second light emitting layer and the partition wall; and
forming a second organic layer to cover the first organic layer and the second encapsulation layer,
wherein the second organic layer is filled in a space formed between an edge portion of the second encapsulation layer and the first organic layer.

18. The method of claim 17, further comprising:
forming a third partition wall opening by etching the partition wall through an opening of the second organic layer;
forming a third light emitting opening overlapping the third partition wall opening by etching the pixel defining layer; and
forming a third light emitting layer in the third light emitting opening and the third partition wall opening.

19. The method of claim 18, further comprising:
forming a third encapsulation layer on the third light emitting layer and the partition wall; and
forming a third organic layer to cover the second organic layer and the third encapsulation layer,
wherein the third organic layer is filled in a space formed between an edge portion of the third encapsulation layer and the second organic layer.

20. An electronic device comprising:
a processor to provide input image data; and
a display device to display an image based on the input image data,
wherein the display device comprises:
a first electrode;
a pixel defining layer on the first electrode, wherein a light emitting opening is defined through the pixel defining layer;
a partition wall on the pixel defining layer, wherein a partition wall opening overlapping the light emitting opening is defined through the partition wall;
a light emitting layer in the light emitting opening and the partition wall opening;
a second electrode on the light emitting layer;
an encapsulation layer on the second electrode and the partition wall; and
an organic layer covering the encapsulation layer,
wherein an edge portion of the encapsulation layer is spaced apart from the partition wall, and
wherein the organic layer is filled in a space between the edge portion of the encapsulation layer and the partition wall.
